(19) United States
(12) Patent Application Publication
(10) Pub. No.: US 2013/0094669 A1
(43) Pub. Date: Apr. 18, 2013

(54) AUDIO SIGNAL PROCESSING APPARATUS, AUDIO SIGNAL PROCESSING METHOD AND A PROGRAM

(71) Applicants: Akifumi Kono, Tokyo (JP); Toru Chinen, Kanagawa (JP); Minoru Tsuji, Chiba (JP)

(72) Inventors: Akifumi Kono, Tokyo (JP); Toru Chinen, Kanagawa (JP); Minoru Tsuji, Chiba (JP)

(73) Assignee: SONY CORPORATION, Tokyo (JP)

(21) Appl. No.: 13/602,912

(22) Filed: Sep. 4, 2012

(30) Foreign Application Priority Data
Oct. 14, 2011 (JP) 2011-226945
Feb. 2, 2012 (JP) 2012-020463

(51) Int. Cl. H03G 3/20

(52) U.S. Cl. 381/107

(57) ABSTRACT

An audio signal processing apparatus which includes an input analysis unit which analyses the characteristics of an input signal and generates an input sound feature value; an environment analysis unit which analyses the characteristics of the environmental sound and generates an environmental sound feature value; a mapping control information generation unit which generates mapping control information as control information of amplitude conversion processing to the input signal by application of the input sound feature value and the environmental sound feature value; and a mapping process unit which performs amplitude conversion on the input signal based on a linear or non-linear mapping function determined according to the mapping control information and generates an output signal.

### BACKGROUND

The present disclosure relates to an audio signal processing apparatus, an audio signal processing method, and a program. The present disclosure specifically relates to, for example, a method of optimally automatically controlling reproduction level of the audio signal for the user.

For example, in a case where the audio of movie content and music content in which the dynamic range of the volume of the audio is great, is reproduced using a portable device with a built-in compact speaker, not only is the volume of the audio on the whole reduced, but speech or the like of a low volume in particular becomes difficult to hear.

Specifically, in a compact device, for example, as shown in FIG. 1, (A) is a PC including a compact microphone and a compact speaker and (B) is a portable terminal including a compact microphone and a compact speaker, the size of the speaker is limited, a sufficient output volume is not obtained, and there is a problem in that speech and the like of a low volume becomes difficult to hear.

As technology for making the audio of the content easier to hear, there is technology which adjusts volume of the audio such as normalizing and automatic gain control. However, in such volume control, if read-ahead of sufficiently long data is not performed, it becomes an unstable control from a viewpoint of audibility.

In addition, there is also technology which boosts the small portions of the volume of the audio and compresses a portion of great volume by compression processing of the dynamic range of the volume. However, in the compression processing, when the features of the boost and the compression of the volume are assumed to be generic, it is difficult to produce high emphasis effect of the audio, and in order to obtain a high effect, it is necessary to change the features for each item of content.

For example, the dynamic range compression in Dolby AC3 (Audio Codec number 3), using the sound pressure level specified by the dialogue normalizing as a reference, is technology which boosts signals of a sound pressure level which is lower than the reference and compresses signals of a sound pressure level which is greater than the reference. However, in this technology, in order to obtain a sufficient effect, it is necessary to specify the sound pressure level for dialogue normalization, and the features of the boost and compression when the audio signal is encoded.

Furthermore, technology has been proposed in which when compressing the dynamic range of the volume of the audio, coefficients determined by an average value of an absolute value of the audio signal are multiplied by the audio signal, therefore making sounds with a small volume of an audio signal easier to hear (for example, refer to Japanese Unexamined Patent Application Publication No. 05-275950).

### SUMMARY

In recent years, users have carried various portable equipments with compact built-in speakers in various environments, such as various quiet environments and noisy environments, and have begun to listen to various types of content such as movies, music, self recorded content, and the like. However, depending on the magnitude of the peripheral environmental sound, even the same reproduction volume may be too great or too small. Therefore, in such portable equipment, technology which optimally performs automatic control on the volume of various content items according to the magnitude of the environmental sound is necessary.

It is desirable to provide an audio signal processing apparatus, an audio signal processing method and a program which optimally perform automatic control on the reproduction level of the audio signal in accordance with the size of the sound of the environment.

According to an embodiment of the present disclosure, there is provided an audio signal processing apparatus including: an input analysis unit which analyses the features of an input signal and generates an input sound feature value; an environment analysis unit which analyses the features of the environmental sound and generates an environmental sound feature value; a mapping control information generation unit which generates mapping control information as control information of amplitude conversion processing to the input signal by application of the input sound feature value and the environmental sound feature value; and a mapping process unit which performs amplitude conversion on the input signal based on a linear or non-linear mapping function determined according to the mapping control information and generates an output signal.

The mapping control information generation unit may include a mapping control information determination unit which generates preliminary mapping control information by application of the input sound feature value; and a mapping control information adjustment unit which generates the mapping control information which is output to the mapping process unit by an adjustment process in which the environmental sound feature value is applied to the preliminary mapping control information.

The input analysis unit may calculate a root mean square which is calculated by using a plurality of sequential samples which are defined in advance as the input sound feature values; the environment analysis unit calculates a root mean square which is calculated by using a plurality of sequential samples of the environmental sound signal as the environmental sound feature value; and the mapping control information generation unit generates the mapping control information by using the root mean square of the input signal which is the input sound feature value and the root mean square of the environmental sound signal which is the environmental sound feature value.

The input sound feature value and the environmental sound feature value may be a mean square, a logarithm of a mean square, a root mean square, a logarithm of a root mean square, the zero crossing rate, the slope of a frequency envelope, or the result of a weighted sum of all of the above, with regard to a feature value calculation target signal.

The environment analysis unit may calculate the environmental sound feature values by executing feature analysis of a signal of a band of a high occupancy ratio of the environmental sound which has been divided by a band division process from a sound acquisition signal which has been acquired via a microphone.

The audio signal processing apparatus may have a band restriction unit which executes a band restriction process of a signal, to which a mapping process has been applied, in the mapping process unit, and a signal is output via a speaker after band restriction in the band restriction unit.

The mapping control information generation unit may apply a mapping control model which has been generated by a statistical analysis process to which a signal for learning, which includes an input signal and an environmental sound signal, is applied, and generates the mapping control information.

The mapping control model may be data in which the mapping control information is associated with the various types of the input signal and the environmental sound signal.

The input signal may include a plurality of input signals of a plurality of channels, and the mapping process unit is configured to execute separate mapping processes on each of the input signals.

The audio signal processing apparatus may further include a gain adjustment unit which executes gain adjustment corresponding to the environmental sound feature value generated by the environment analysis unit in regard to a mapping process signal generated by the mapping process unit.

According to another embodiment of the present disclosure, there is provided an audio signal processing method which is executed in an audio signal processing apparatus including: analyzing characteristics of an input signal and generating an input sound feature value; analyzing characteristics of an environmental sound and generating an environmental sound feature value; generating mapping control information as control information of amplitude conversion processing to the input signal by application of the input sound feature value and the environmental sound feature value; and performing amplitude conversion on the input signal based on a linear or non-linear mapping function determined according to the mapping control information and generates an output signal.

According to still another embodiment of the present disclosure, there is provided a program which executes audio signal processing in an audio signal processing apparatus including: analyzing characteristics of an input signal and generating an input sound feature value; analyzing characteristics of an environmental sound and generating an environmental sound feature value; generates mapping control information as control information of amplitude conversion processing to the input signal by application of the input sound feature value and the environmental sound feature value; and performing amplitude conversion on the input signal based on a linear or non-linear mapping function determined according to the mapping control information and generates an output signal.

Furthermore, the program of the present disclosure is, for example, in regard to a general purpose system which is capable of executing various items of program code, a program which is possible to provide using a storage medium or a communications medium which is provided in a computer readable format. Processing which corresponds to a program on a computer system is realized by providing such a program in a computer readable format.

Furthermore, other aims, characteristics and merits of the present disclosure will become clear due to a detailed description based on the embodiments and attached figures of the present embodiment described later. Furthermore, the system in the present specification is a logical collection of configurations of a plurality of apparatuses, and the apparatus of each configuration is not limited to being within the same housing.

According to a configuration of an example of the present disclosure, when the environmental sound is great or small, optimal mapping control becomes possible, user dissatisfaction such as insufficient volume, or distortion, causing discomfort is reduced, and the reproduction level of an audio signal may be optimally automatically controlled for the user, even in various environments.

Specifically, for example, the characteristics of an input signal are analyzed and an input sound feature value is generated, the characteristics of the environmental sound are analyzed and an environmental sound feature value is generated, the input sound feature value and the environmental sound feature value which have been generated are applied and the mapping control information is generated as control information of amplitude conversion processing to the input signal. Furthermore, based on a linear or non-linear mapping function determined according to the mapping control information, amplitude conversion is performed on the input signal and an output signal is generated. The mapping control information is generated with reference to the model which has been generated with consideration of the input signal and the environmental sound, for example. According to these configurations, optimally performing automatic control on the level of an audio signal in various environments is possible due to optimal mapping control corresponding to environmental sound.

### BRIEF DESCRIPTION OF THE DRAWINGS

FIG. 1 is a diagram illustrating examples of an apparatus which includes a compact speaker;

FIG. 2 is a block diagram which shows an example of an audio signal processing method in the first embodiment of the present disclosure;

FIG. 3 is a diagram which shows an example of frequency band categorization when band division of the sound acquisition signal is performed in the first to eighth embodiments of the present disclosure;

FIG. 4 is an example of a function graph of a mapping control information adjustment amount in the first embodiment of the present disclosure;

FIG. 5 is an example of a function graph of mapping in the first embodiment of the present disclosure;

FIG. 6 is a block diagram which shows an example of an audio signal processing method in the second embodiment of the present disclosure;

FIG. 7 is a block diagram which shows an example of an audio signal processing method in the third embodiment of the present disclosure;

FIG. 8 is a block diagram which shows an example of a model learning method of the mapping control in the third embodiment of the present disclosure;

FIG. 9 is a flowchart which shows an example of an application method of the mapping control information in the third embodiment of the present disclosure;

FIG. 10 is an example of a graph of a regression curve according to a mapping control model in the third embodiment of the present disclosure;

FIG. 11 is a block diagram which shows an example of a sound signal processing method in the fourth embodiment of the present disclosure;

FIG. 12 is a block diagram which shows an example of a model learning method of the mapping control in the fourth embodiment of the present disclosure;

FIG. 13 is a flowchart which shows an example of an application method of the mapping control information in the fourth embodiment of the present disclosure;

FIG. 14 is a block diagram which shows an example of a sound signal processing method in the fifth embodiment of the present disclosure;

FIG. 15 is a block diagram which shows an example of a sound signal processing method in the sixth embodiment of the present disclosure;

FIG. 16 is a block diagram which shows an example of a sound signal processing method in the seventh embodiment of the present disclosure;

FIG. 17 is a block diagram which shows an example of a sound signal processing method in the eighth embodiment of the present disclosure.

### DETAILED DESCRIPTION OF EMBODIMENTS

Below, detailed description will be given of an audio signal processing apparatus, an audio signal processing method, and a program of the present disclosure with reference to the figures.

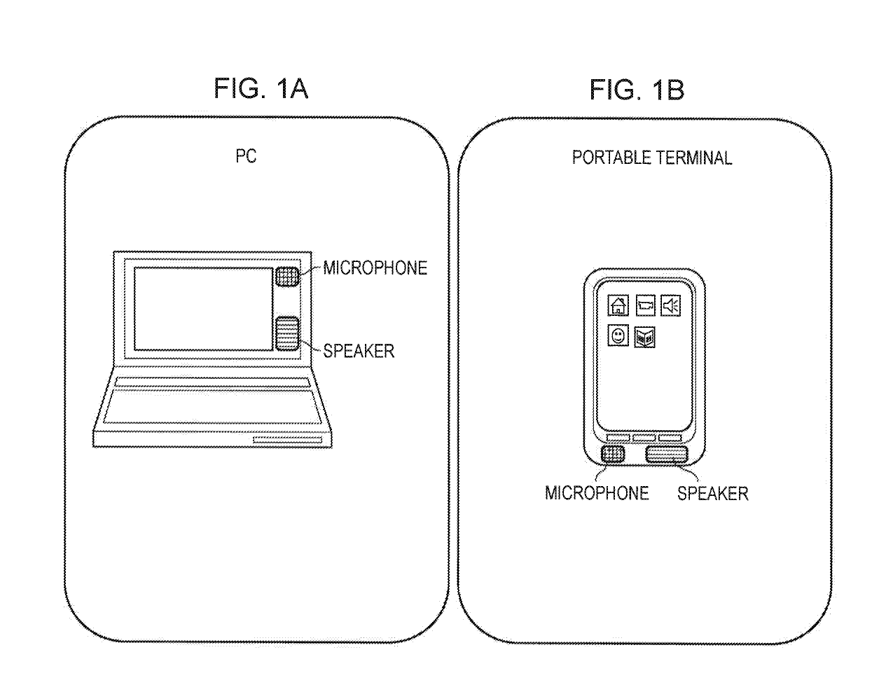

Furthermore, the audio signal processing apparatus of the present disclosure performs control of an output sound from a speaker of an apparatus or the like which includes a compact speaker as described with reference to FIG. 1 earlier, for example, and the audio signal processing apparatus of the present disclosure performs audio signal processing to make an output sound easier to hear even in an environment in which environmental sound of various periphery noises and the like occurs. Specifically, for example, a process or the like of optimally automatically controlling the reproduction level of the audio signal according to environmental sound is performed.

Description will be given in order according to the items below regarding the plurality of the audio signal processing apparatuses according to embodiments of the present disclosure.

1. Regarding the first embodiment
2. Regarding the second embodiment
3. Regarding the third embodiment
4. Regarding the fourth embodiment
5. Regarding the fifth embodiment
6. Regarding the sixth embodiment
7. Regarding the seventh embodiment

### 1. Regarding the First Embodiment

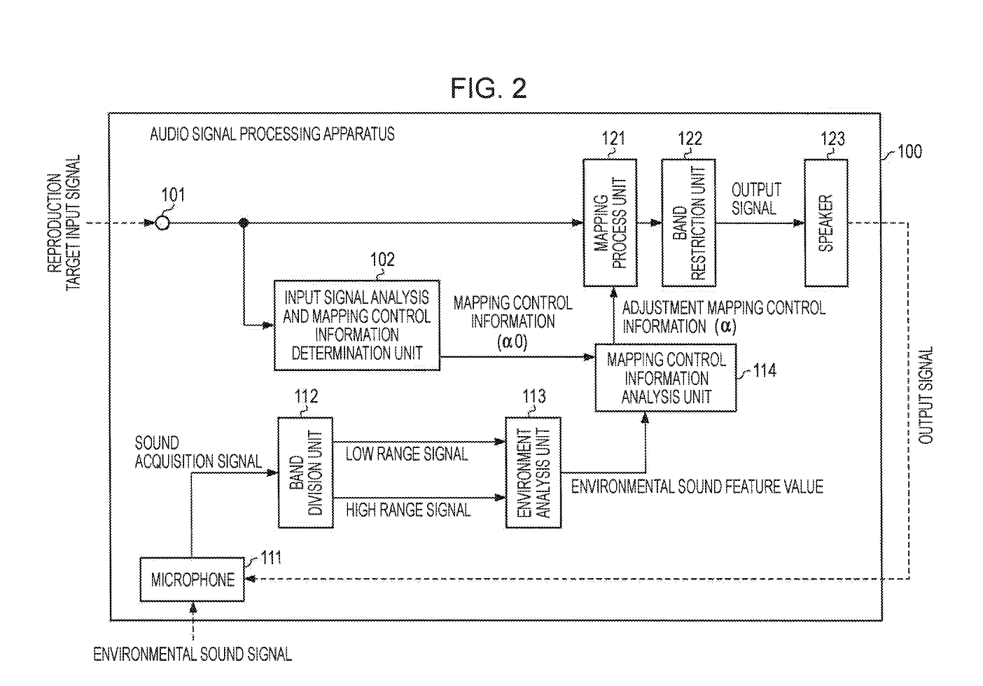

A block diagram of an audio signal processing apparatus in the first embodiment of the present disclosure will be shown in FIG. 2.

The audio signal processing apparatus 100 shown in FIG. 2 may be configured as an internal apparatus of an information processing apparatus of the (A) PC, (B) portable terminal or the like described with reference to FIG. 1 earlier, for example, or may also be configured as an independent apparatus which connects to various audio output apparatuses and performs processing on an audio signal output from the audio output apparatus.

The audio signal processing apparatus 100 shown in FIG. 2 is configured as shown below. The audio signal processing apparatus 100 is configured by an input unit 101, an input signal analysis and mapping control information determination unit 102, a microphone 111, a band division unit 112, an environment analysis unit 113, a mapping control information adjustment unit 114, a mapping process unit 121, a band restriction unit 122, and a speaker 123.

The input unit 101 is the input unit of the audio signal which is the reproduction target. In the information processing apparatuses of the (A) PC, (B) portable terminal, or the like as shown in FIG. 1, for example, the input unit 101 is the input unit of the audio signal which has been generated by the reproduction signal generation unit inside the information processing apparatus. Alternatively, it may correspond to the input unit or the like which has been connected to the audio output unit of the external audio reproduction apparatus. The audio signal processing apparatus shown in FIG. 2 includes a microphone 111 and a speaker 123 in the same manner as the PC and portable terminal shown in FIG. 1.

The reproduction target input signal input from the input unit 101 is input to the input signal analysis and mapping control information determination unit 102.

The input signal analysis and mapping control information determination unit 102 performs analysis of the features of the input audio signal.

Specifically, the input signal analysis and mapping control information determination unit 102 calculates and outputs the root mean square RMS (n) of N samples, which are centered on the n-th sample of the input signal from the input unit 101, according to the Expression 1 shown below.

$$R M S ( n ) = 20.0 \times {log}_{10} ( \sqrt{\frac{1}{N} \cdot {\sum }_{m = n - N / 2}^{m + n / 2 - 1} {x}^{2} ( m )} ) \qquad [ Expression 1 ]$$

In the above Expression 1, x is the reproduction target input signal which has been input from input unit 101, and, for example, is the data of the audio level which is normalized to a value from −1.0 to 1.0.

The input signal analysis and mapping control information determination unit 102 calculates the root mean square EMS (n) as the feature value corresponding to the n-th sample, according to the above Expression 1 by using N sequential samples which are defined in advance centered on the n-th sample with the process target signal as the n-th sample signal.

The input signal analysis and mapping control information determination unit 102 supplies the root mean square RMS (n) which has been calculated according to the Expression 1 above to the mapping control information adjustment unit 114 as mapping control information α0 which corresponds to the n-th input sample signal.

Furthermore, in the process example described above, the mapping control information calculated by the input signal analysis and mapping control information determination unit 102 is a process example using the root mean square EMS (n). However, as the mapping control information, besides the root mean square EMS (n), it is possible to use various analyzed feature values such as the t-th power value (t>=2), the zero crossing rate, and the slope of the frequency envelope, with regard to the EMS (n). A configuration may also be employed in which data to which the various feature values related to the input signals are arbitrarily added and combined, for example, the mapping control information α0 is generated based on the result of a weighted sum and supplied to the mapping control information adjustment unit 114.

The mapping control information adjustment unit 114 performs adjustment of the mapping control information corresponding to the magnitude of the environmental sound in regard to the mapping control information α0 which has been input from the input signal analysis and mapping control information determination unit 102.

Furthermore, the environmental sound is the sound included in the sound acquisition signal of the microphone 111.

The peripheral pure environmental sound and the output signal which is output from the speaker 123 of the audio signal processing apparatus 100 are included in the signal sound acquired from the microphone 111 (the sound acquisition signal).

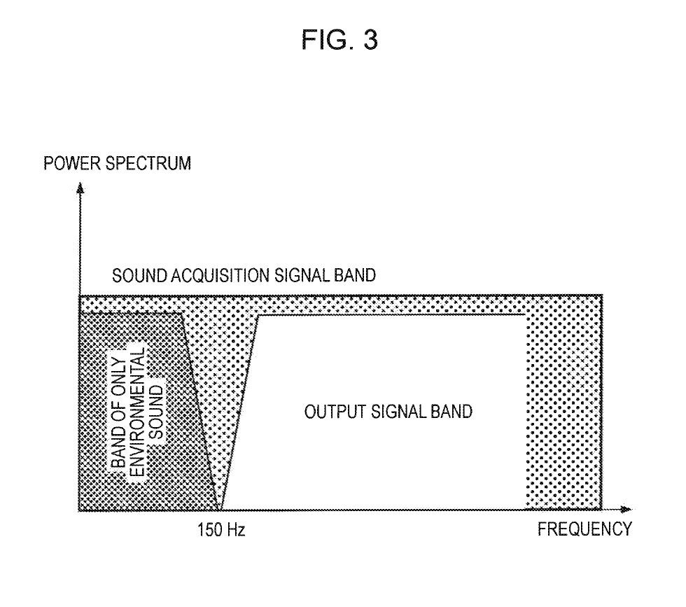

In other words, as shown in FIG. 3, the output signal from the speaker is also included with the peripheral sound (environmental sound).

Furthermore, in the description below, the environmental sound includes all of the sounds from the sound acquisition signal of the microphone 111 except for the output signal from the speaker 123 of the audio signal processing apparatus 100. In other words, the environmental sound includes various peripheral sounds and noise, for example, even voice emitted by the user themselves, noise emitted from the apparatus itself, and the like are included.

FIG. 3 is an example of analysis data of the signal sound acquired from the microphone 111 (the sound acquisition signal), and is a diagram which shows the frequency on the horizontal axis and the power spectrograph on the vertical axis.

For example, as an example, as shown in FIG. 3, characteristics in which the band equal to or less than frequency=150 Hz is the environmental sound, and the proportion occupied by the output signal from the speaker 123 is large in the band equal to or above 150 Hz may be obtained. Furthermore, the reason that the environmental sound and the speaker output signal are separated with the frequency=150 Hz as shown in FIG. 3 as the boundary, is that band restriction is being performed on the output signal from the speaker 123 using the band restriction unit 122 of the previous stage to the speaker 123. In other words, this is due to performing band restriction on the output signal from the speaker 123 at an earlier stage than the microphone 111 performs the sound acquisition. This band restriction process will be described in detail later.

In the band division unit 112, the sound acquisition signal of the microphone 111 is divided into a low range signal of below 150 Hz which is a frequency band which only includes the environmental sound, and a high range signal which, in addition to the environmental sound, also includes the output signal from the speaker 123.

Furthermore, in the process example, the sound acquisition signal is divided into two at 150 Hz to correspond to the characteristics described with reference to FIG. 3, however, it is sufficient to be able to divide the sound acquisition signal into a band which only includes the environmental sound and a band excluding this, and it is favorable to perform division at a frequency suitable for audibility and analysis.

In addition, in advance, when the band of the signal which is input from the input unit 101 is ascertained, division processing may be performed in accordance with the input signal. Specifically, for example, when the input signal from the input unit 101 is a signal where the low range and the high range have been cut, the sound acquisition signal is divided into three ranges of a low range, a middle range and a high range, and for each divided region unit, the sound acquisition signal may be sorted into a region of only the environmental sound and a mixed region of the environmental sound and the output signal from the speaker.

The sound acquisition signal which has been divided in the band division unit 112 is input to the environment analysis unit 113.

The environment analysis unit 113 calculates the feature value of the environmental sound. In other words, in the present process example, among the sound acquisition signals which were divided in the band division unit 112, most calculate a feature value of a low range signal which is estimated to be configured from environmental sound.

Specifically, they are supplied to the mapping control information adjustment unit 114 with the root mean square RMS (k) of K samples, centered on the k-th sample of a low range signal of a high occupancy ratio of the environmental sound among the sound acquisition signals which were divided in the same manner as in the above Expression 1, as the analyzed feature value.

Furthermore, in the feature value of the environmental sound in the environment analysis unit 113, data in which various analyzed feature values such as, besides the root mean square EMS (k), the t-th power value (t>=2), the zero crossing rate, the slope of the frequency envelope, and the like with regard to the RMS (n), are arbitrarily added and combined, for example, the result of a weighted sum may be used.

In addition, when a band signal which only includes the environmental sound is only a high range, or is both a low range and a high range, the analyzed feature value of only the high range signal, or the analyzed feature value which has been obtained from the low range signal and the high range signal is applied. According to the mixing ratio of the environmental sound, the weighted sum or the like of the analyzed feature value of the low range and the analyzed feature value of the high range is calculated, and this may be used as the final analyzed feature value of the environmental sound.

Furthermore, in the present embodiment, the analyzed feature value is obtained from the band divided signal in which the reproduction band of the speaker 123 is removed, however, it is also possible to obtain the analyzed feature value of the middle range signal which is not an analysis target or the signal of the entire frequency band from the analyzed feature value of the band divided signal of only the low range, only the high range, or both the low range and the high range without the middle range by using a statistical model based on a function, a table, or previously performed statistical analysis.

For example, when the band signal is divided by two and the high range is missing, the low range signal is divided into a plurality of sub-bands, the mean and the slope of the root mean square of each sub-band signal are set as an explanatory variable, the root mean square of each sub-band signal when the missing high range is divided into sub-bands in the same manner is set as an explained variable, the regression estimate is performed, and the result thereof may be set as the final analyzed feature value.

Furthermore, here, description has been given with the assumption that the microphone 111 is a monaural microphone, however, the microphone 111 may also be configured as two or more microphones. In such a case, band division is performed per microphone, and the respective signals are supplied to the environment analysis unit 113.

In addition, the difference, the correlation, the estimated sound source direction, and the like of the signal from each microphone may also be set to the analyzed feature value in addition to the previously described analyzed feature value.

The environmental sound feature value, which is the feature value of the environmental sound which has been calculated by the environment analysis unit 113, is input to the mapping control information adjustment unit 114.

The mapping control information adjustment unit 114 inputs the mapping control information α0 which is a feature value, corresponding to the n-th input sample signal, which has been input from the input signal analysis and mapping control information determination unit 102, and inputs the feature value of the environmental sound which has been circulated by the environment analysis unit 113.

There are, for example, both root mean square RMS values which were calculated in accordance with the previously described Expression 1.

The mapping control information adjustment unit 114 performs adjustment of the mapping control information α0 which is a feature value corresponding to the n-th input sample signal, based on the environmental sound feature value obtained from the environment analysis unit 113, and supplies the result to the mapping process unit 121.

The mapping control information adjustment unit 114, for example, obtains the mapping control information adjustment amount y by using a non-linear function such as that shown below in Expression 2. x is the environmental sound feature value RMS

y=px²+qx+r [Expression 2]

Furthermore, p, q, and r are parameters which are defined in advance.

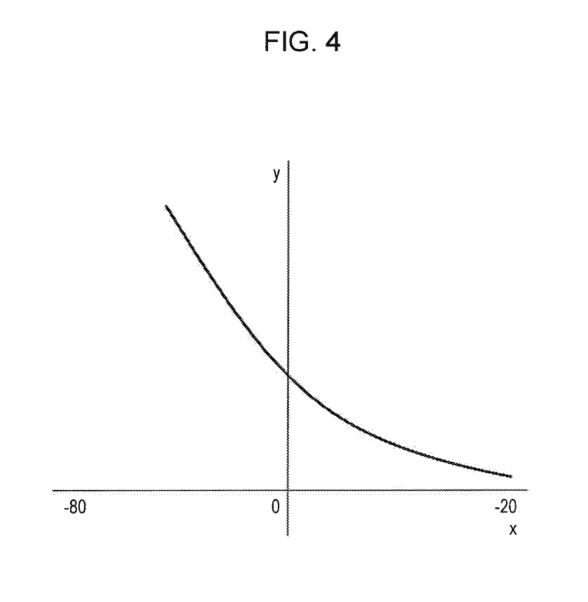

A graph which corresponds to the above Expression 2 is shown in FIG. 4.

The graph of FIG. 4 is a graph where the horizontal axis (x) and the vertical axis (y) are set as shown below.
x: environmental sound feature value RMS (k)
y: mapping control information adjustment amount
The graph shows the correlation of these.

The horizontal axis (x) corresponds to the power (db) of the environmental sound. This means that the power of the environmental sound gets larger the further in the rightward direction one progresses. The greater the environmental sound is, the smaller the mapping control information adjustment amount y becomes, and the smaller is environmental sound is, the larger the mapping control information adjustment amount y becomes.

Furthermore, in this embodiment, the non-linear function shown in the above Expression 2 is used for the calculation processing of the mapping control information adaptation amount y, however, a linear or non-linear function, a table, a linear regression model, or a non-linear regression model, which represent the relationship between the environmental sound feature value and the mapping control information adjustment amount, may also be used.

The mapping control information adjustment unit 114 uses the mapping control information adjustment amount y which has been calculated using Expression 2, further uses a function such as the Expression 3 shown below, and adjusts the mapping control information α0 which is a feature value corresponding to the input sample signal which is input from the input signal analysis and mapping control information determination unit 102.

α=α₀+y [Expression 3]

In the above Expression 3, α0 is the mapping control information RMS (n) which is a feature value in regard to the input sample signal which is input from the input signal analysis and mapping control information determination unit 102, and α is the mapping control information after adjustment.

As described earlier with reference to FIG. 4, the greater the environmental sound is, the smaller the mapping control information adjustment amount y becomes, and the smaller is environmental sound is, the larger the mapping control information adjustment amount y becomes. Therefore, the value of the mapping control information α after adjustment is adjusted as shown below. The greater the environmental sound is, the smaller the value of the mapping control information α after adjustment becomes, and the smaller the environmental sound is, the larger the value of the mapping control information α after adjustment becomes.

Furthermore, in this embodiment, as the calculation process of the mapping control information α after adjustment, calculating the mapping control information adjustment amount y, which has been calculated using Expression 2 for the mapping control information α0 which is a feature value corresponding to an input sample signal, has been exemplified, however, the values thereof are multiplied, and calculation of the mapping control information α after adjustment may also be performed using, for example,

α=α0×y

the above formula. Alternately, a configuration of a linear or non-linear function, a table, a linear regression model, or a non-linear regression model may also be used.

As described above, the mapping control information adjustment unit 114 applies the environmental sound feature value x (=RMS (k)), obtains the mapping control information adjustment amount y by using the non-linear function (FIG. 4) shown in Expression 2, furthermore, uses the mapping control information adjustment amount y, and calculates the adjustment value of the mapping control information α0, in other words, the adjustment mapping control information a which is a feature value corresponding to the input sample signal which is input from input signal analysis and mapping control information determination unit 102.

The adjustment mapping control information a which has been calculated by the mapping control information adjustment unit 114 is input to the mapping process unit 121. The mapping process unit 121 uses a non-linear function such as that shown below in Expression 4 as a mapping function, converts the amplitude of the reproduction target input signal which is input from the input unit 101, and outputs to the band restriction unit 122.

$$f ( x ) = \frac{α}{α - 1} ( x - \frac{1}{α} {x}^{3} ) \\ ( - 1.0 \leq x \leq 1.0 ) \qquad [ Expression 4 ]$$

Furthermore, in the above Expression 4, x is, for example, an input sample signal where the power has been normalized in a range of −1.0 to 1.0, and α is the mapping control information after adjustment which has been supplied from mapping control information adjustment unit 114.

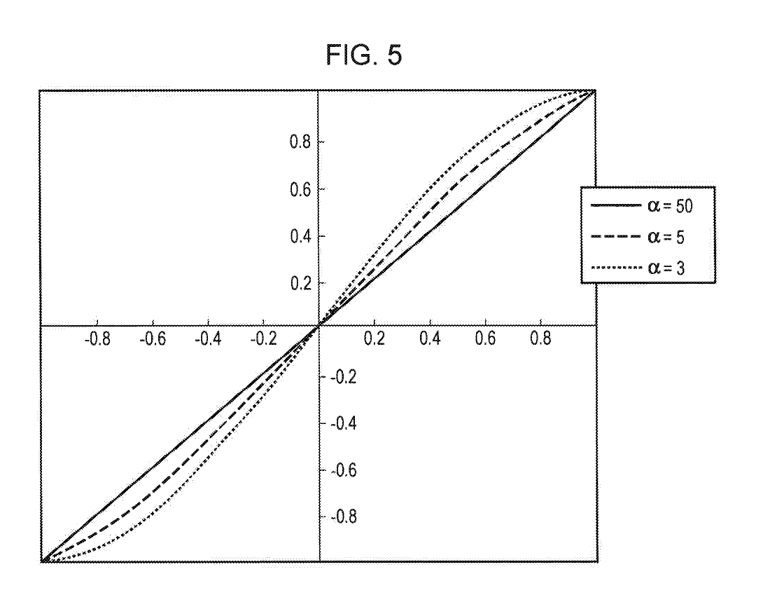

A graph of Expression 4 is shown in FIG. 5.

The horizontal axis is x, in other words, the normalized signal x of −1.0 to 1.0, and the vertical axis is f (x) in other words, the output f (x) which is calculated according to the above Expression 4, and is the mapping function f (x).

In FIG. 5, the value of the mapping control information. α after adjustment which is supplied from the mapping control information adjustment amount unit 114 is exemplified as the following three values of,

α=50,
α=5, and
α=3.

The smaller the mapping control information α after adjustment is, the greater the amplification amount is set to.

As described with reference to Expression 3 earlier, the value of the mapping control information α after adjustment is adjusted as shown below.

The greater the environmental sound is, the smaller the value of the mapping control information α after adjustment becomes, and the smaller the environmental sound is, the larger the value of the mapping control information α after adjustment becomes.

Therefore, the larger the environmental sound is, the greater the amplification amount is set to, and the smaller the environmental sound is, the smaller the amplification amount is set to.

In this manner, the audio signal processing apparatus 100 of the present disclosure executes a process which changes the amplification amount in regard to the input signal by changing the mapping control information α after adjustment according to the environmental sound.

Furthermore, the influence of the changing process of the amplification amount on the input signal changes depending on the magnitude of the mapping control information α0 (=RMS (n)) which is a feature value corresponding to, for example, the n-th input sample signal. In other words, in regard to the n-th input sample signal, when the RMS (n) is small, an amplitude conversion, to which a mapping function of sharp characteristics is applied, is performed, and when the RMS (n) is large, an amplitude conversion, to which a mapping function of gentle characteristics is applied, is performed.

In addition, the amplification amount also changes according to the size of the environmental sound. In other words, as is understood from FIG. 4, FIG. 5, and the previously described Expression 3 and Expression 4, as the feature value RMS (k) (x of FIG. 4) of the environmental sound get larger, in other words, as the environmental sound gets larger, the value of the mapping control information a after adjustment gets smaller, the amplification amount as an adjustment amount as shown in FIG. 5 increases, and an adjustment process of the mapping control information is executed corresponding to the magnitude of the environmental sound.

Furthermore, in this embodiment, a non-linear function has been used for the mapping function, however, a linear function or an exponential function may also be used, and as long as the condition of −1.0≦f (x)≦1.0 is satisfied in regard to an input of −1.0≦x≦1.0, the application of any function is possible. It is favorable to use a function with a suitable processing effect and audibility as the mapping function.

In addition, here, the amplitude conversion in the mapping control unit is controlled by deriving the mapping control information α for each sample of the input signal, however, the amplitude conversion in the mapping control unit may also be controlled by, for example, deriving the control information α for each two or more sequential samples.

In this manner, the mapping process unit 121 uses a non-linear function such as that shown above in Expression 1, in other words, such as that shown in FIG. 5, as a mapping function, converts the amplitude of the reproduction target input signal which is input from the input unit 101, and outputs to the band restriction unit 122.

Finally, the band restriction unit 122 applies the band restriction filter to the input signal, to which amplitude conversion is performed, which is output from the mapping process unit 121, and generates a band restricted output signal. For example, a low range cut process is performed. Specifically, for example, when reproduction is performed using a compact speaker 123, which is an output unit, a process of cutting the low range to a degree that the audible difference is small, even in comparison with before the band restriction, is executed.

Furthermore, instead of performing the band restriction on the input signal, to which amplitude conversion is performed, which is output from the mapping process unit 121, the band restriction unit 122 may perform band restriction on the reproduction target is signal. Furthermore, when the reproducible band is restricted due to the performance of the speaker 123, in other words, when the band restriction is performed inherently when the speaker performs reproduction, it is not necessary to perform band restriction processing again. In addition, the frequency which is cut by the band restriction unit is assumed to be only low range, however, only the high range, or both of the low range and the high range may also be cut.

It is favorable to perform band restriction to a frequency band which is suitable for audibility and for the analysis in the previously described environment analysis unit 113.

As described above, by performing band division on the sound acquisition signal which has been acquired by the microphone 111 and obtaining the appropriate mapping control information adjustment amount from the analysis results of the environmental sound, the optimal mapping control information corresponding to the magnitude of the environmental sound may be obtained, and the optimal reproduction level control may be realized corresponding to the environment for the user.

### 2. Regarding the Second Embodiment

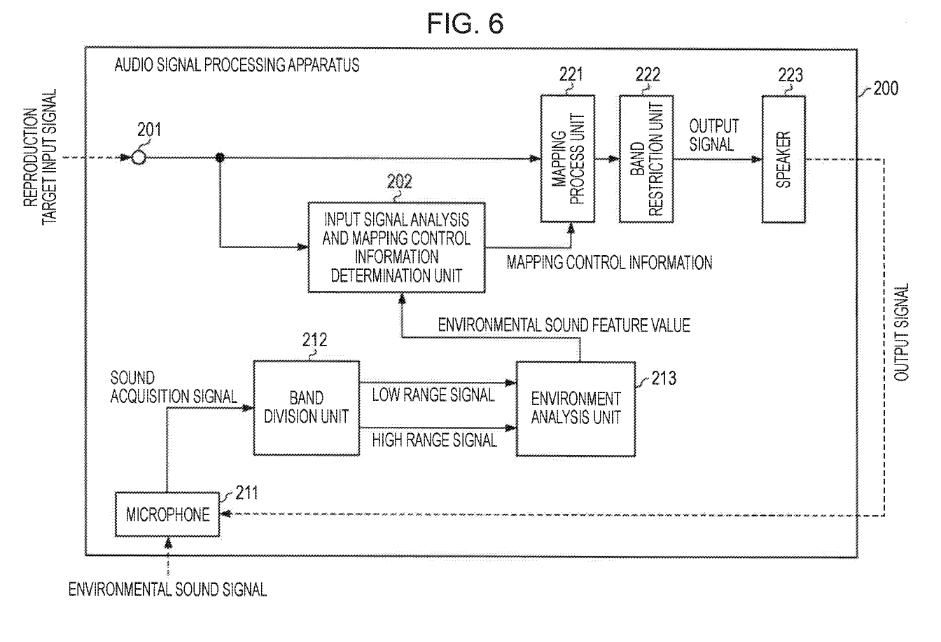

A block diagram of an audio signal processing apparatus in the second embodiment of the present disclosure will be shown in FIG. 6.

The audio signal processing apparatus 200 shown in FIG. 6 includes an input unit 201, an input signal analysis and mapping control information determination unit 202, a microphone 211, a band division unit 212, an environment analysis unit 213, a mapping process unit 221, a band restriction unit 222, and a speaker 223.

The difference between this and the audio signal processing apparatus 100 of the first embodiment described with reference to FIG. 2 is that the mapping control information adjustment unit 114 shown in FIG. 2 is omitted.

In the audio signal processing apparatus 200 of the second embodiment shown in FIG. 6, the input signal analysis and mapping control information determination unit 202 generates the final mapping control information α which is output to the mapping process unit 221.

The processes of the other configurations are the same as in the first embodiment. In other words, band division is performed on the sound acquisition signal which is acquired by the microphone 211, analysis is performed in the environment analysis unit, and environmental sound feature value RMS (k) is obtained.

The input signal analysis and mapping control information determination unit 202 analyses the characteristics of the reproduction target input signal which is input from the input unit 201 and obtains the input sound feature value RMS (n) in the same manner as in the first embodiment. Furthermore, the mapping control information a is obtained from the input sound feature value RMS (n) and the environmental sound feature value RMS (k) by using the function shown below in Expression 5, and is supplied to the mapping process unit 221.

$$α = R M S ( n ) \frac{1}{a} ( R M S ( k ) + b ) \\ ( - b < R M S ( k ) ) \qquad [ Expression 5 ]$$

where a and b are parameters which are defined in advance.

In the present embodiment, in only the input signal analysis and mapping control information determination unit 202, the mapping control information α is obtained from the input sound feature value RMS (n) and the environmental sound feature value RMS (k) by using the function shown above in Expression 5, and is supplied to the mapping process unit 221.

Furthermore, RMS (n) and RMS (k) have also been shown as the analyzed feature values of the input signal and the environmental sound in the second embodiment, however, other analyzed feature values may also be used which are the same as those described in the first embodiment.

The mapping process unit 221 uses a non-linear function such as that described earlier in Expression 4 as the mapping function in the same manner as the previously described first embodiment. In the Expression 4, x is an input sample signal which is normalized in a range of −1.0 to 1.0, and α is the mapping control information.

Below, the mapping process is performed in the same manner as in the first embodiment of the present disclosure, the band restriction is performed in the hand restriction unit 222, and the output signal is output via the speaker 223.

As described above, by performing band division on the sound acquisition signal, analyzing the environmental sound, and obtaining the mapping control information based on the analyzed feature value, the optimal mapping control information corresponding to the magnitude of the environmental sound may be obtained, and the optimal reproduction level control may be realized corresponding to the user and the environment.

### 3. Regarding the Third Embodiment

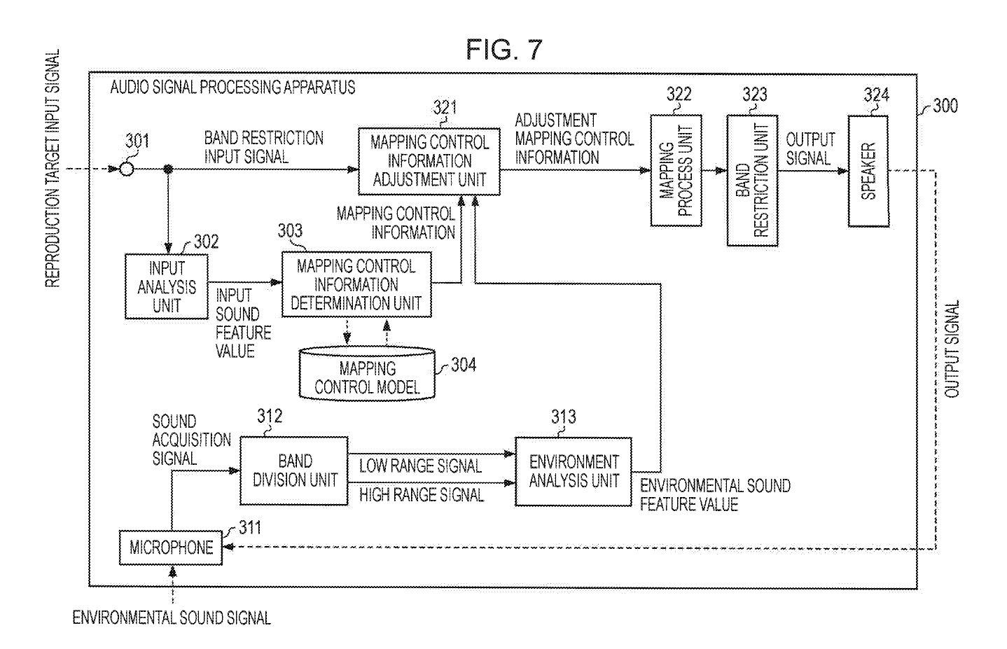

A block diagram of an audio signal processing apparatus 300 according to the third embodiment of the present disclosure will be shown in FIG. 7.

The audio signal processing apparatus 300 shown in FIG. 7 is configured as shown below.

The audio signal processing apparatus 300 is configured by an input unit 301, an input analysis unit 302, a mapping control information determination unit 303, a mapping control model 304 (storage unit), a microphone 311, a band division unit 312, an environment analysis unit 313, a mapping control information adjustment unit 321, a mapping process unit 322, a band restriction unit 323, and a speaker 324.

In FIG. 7, the reproduction target input signal input from the input unit 301 is supplied to the input analysis unit 302, and the characteristics thereof are analyzed.

The input analysis unit 302 calculates the root mean square RMS (n) of N samples, which are centered on the n-th sample of the input signal from the input unit 301, as input sound feature values corresponding to the n-th reproduction target input signal, according to the Expression 1 which has been described earlier in the first embodiment, and supplies them to the mapping control information determination unit 303.

Furthermore, the analyzed feature value is not limited to RMS (n), and the previously described other analyzed feature value may be used, or arbitrarily added and combined.

Next, in the mapping control information determination unit 303, the mapping control information, which corresponds to the analyzed feature value which has been input, is obtained by using the mapping control model 304, which has been generated by the learning process which has been executed in advance, and is supplied to the mapping control information adjustment unit 321.

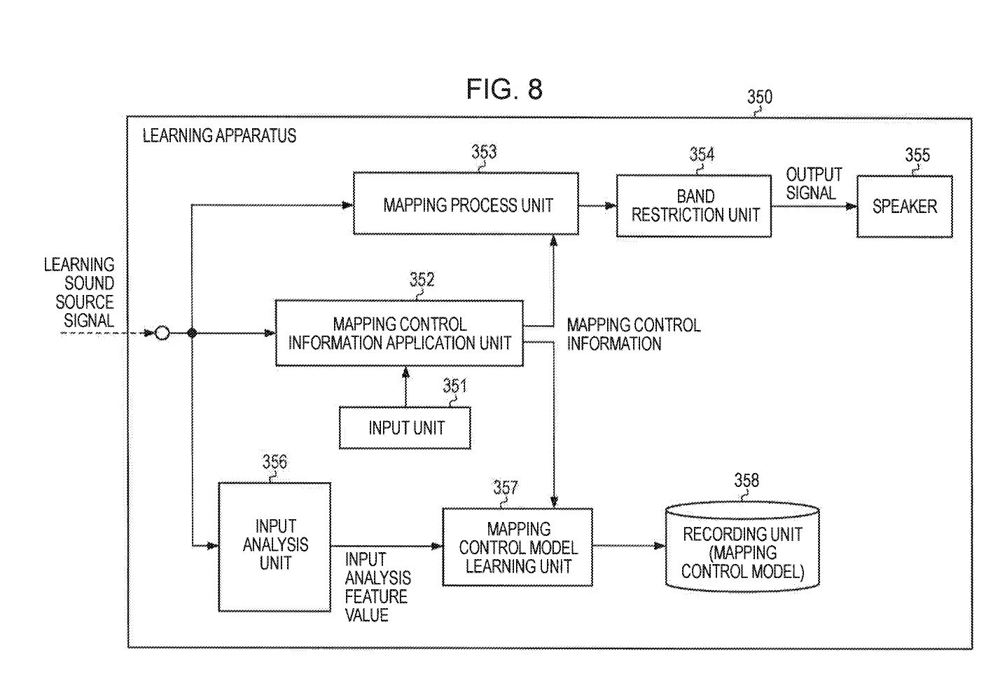

The mapping control model 304 is generated in advance based on statistical analysis to which the learning process, in other words the learning data, is applied. The generation method of the mapping control model 304 will be described with reference to FIG. 8. FIG. 8 is a view which shows the configuration of the learning apparatus 350 which executes the learning process, in other words a statistical analysis process, which generates the mapping control model 304.

The learning apparatus 350 shown in FIG. 8 is configured from an input unit 351, a mapping control information application unit 352, a mapping process unit 353, a band restriction unit 354, a speaker 355, an input analysis unit 356, a mapping control model learning unit 357, and a recording unit 358. In the learning apparatus 350, the learning sound source signal used for the learning of the mapping control model is supplied to the mapping control information application unit 352, the input analysis unit 356, and the mapping process unit 353.

The input unit 351 is, for example, formed from a button or the like which is operated by a user, and supplies a signal which corresponds to the operation of the user to the mapping control information application unit 352. The mapping control information application unit 352 applies the mapping control information to each sample of the supplied learning sound source signal according to the signal from the input unit 351, and supplies them to the mapping process unit 353 or the mapping control model learning unit 357.

The mapping process unit 353 performs mapping process on the supplied learning sound source signal by using the mapping control information from the mapping control information application unit 352, and supplies the learning output signal obtained as a result to the band restriction unit 354. The band restriction unit 354, for example, performs the band restriction process of the low range cut or the like, and supplies the process signal to the speaker 355. The speaker 355 reproduces audio based on the learning output signal which has been generated by the mapping process unit 353.

The input analysis unit 356 analyses the characteristics of the supplied learning sound source signal, and supplies the analyzed feature value which shows the analysis results thereof to the mapping control model learning unit 357. The mapping control model learning unit 357 obtains the mapping control model using the statistical analysis, which uses the analyzed feature value from the input analysis unit 356 and the mapping control information from the mapping control information application unit 352, and supplies the mapping control model to the recording unit 358.

The recording unit 358 records the mapping control model which has been supplied from the mapping control model learning unit 357. In this manner, the mapping control model which has been recorded to the recording unit 358 is recorded to the recording unit of the audio signal processing apparatus 300 shown in FIG. 7 as a mapping control model 304.

Furthermore, the learning apparatus 350 shown in FIG. 8 may be configured inside of the audio signal processing apparatus 300 shown in FIG. 7, and may also be configured as an external apparatus. When the learning apparatus 350 shown in FIG. 8 is configured inside of the audio signal processing apparatus 300 shown in FIG. 7, the constituent components of the audio signal processing apparatus 300 may be applied as the constituent components of the learning apparatus in regard to the constituent components which are common with the constituent components of the audio signal processing apparatus 300 shown in FIG. 7 among the constituent components of the learning apparatus shown in FIG. 8.

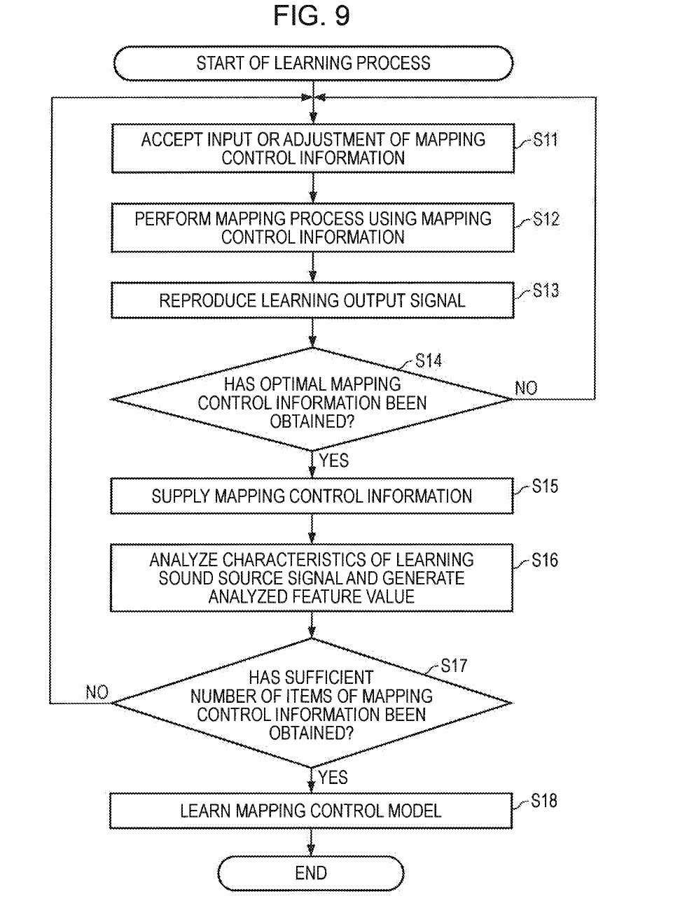

Next, the learning process of the learning apparatus 350 shown in FIG. 8 will be described with reference to the flowchart shown in FIG. 9. In the learning process, one or a plurality of learning sound source signals are supplied to the learning apparatus 350. In addition, in this case, the input analysis unit 356, the mapping process unit 353, the speaker 355, and the like are the same as each block which corresponds to the input analysis unit 302 and the mapping process unit 322 of the audio signal processing apparatus 300, and the like to which the mapping control model which is obtained by learning is supplied. In other words, the characteristics of the blocks and the algorithms of the process are the same.

In step S11, the input unit 351 accepts the input or the adjustment of the mapping control information from the user.

For example, when the learning sound source signal is input, the mapping process unit 353 supplies the supplied learning sound source signal to the speaker 355, and makes the speaker 355 output audio based on the learning sound source signal. Then, the user, while listening to the audio which is output, operates the input unit 351 with a predetermined sample of the learning sound source signal as the processing target sample, and instructs the application of the mapping control information to the processing target sample.

Furthermore, the instruction of the mapping control information application is performed by, for example, the user directly inputting the mapping control information, specifying the desired of several items of mapping control information. In addition, instructing application of the mapping control information may also be performed by the user instructing an adjustment of the mapping control information which had been specified once.

When the user operates the input unit 351 in this manner, the mapping control information application unit 352 applies the mapping control information to the processing target sample according to the operation of the user. Furthermore, the mapping control information application unit 352 supplies the mapping control information which has been applied to the processing target sample to the mapping process unit 353.

In step S12, the mapping process unit 353 performs mapping process on the processing target sample of the supplied learning sound source signal by using the mapping control information which has been supplied from the mapping control information application unit 352, and supplies the learning output signal obtained as a result to the speaker 355.

For example, the mapping process unit 353 substitutes the sample value x of the processing target sample of the learning sound source signal into the non-linear mapping function f (x) shown in the previously described Expression 4, and performs amplitude conversion. In other words, the value, which has been obtained by substituting the sample value x into the mapping function f (x), is the sample value of the processing target sample of the learning output signal.

Furthermore, the sample value x of the learning sound source signal in the Expression 4 is normalized so as to be a value of from −1 to 1. In addition, in the Expression 4, a shows the mapping control information.

Such a mapping function f (x), as shown in FIG. 5, is a function in which the smaller the mapping control information α is, the sharper the function changes. Furthermore, in FIG. 5, the horizontal axis shows the sample value x of the learning sound source signal, and the vertical axis shows the value of the mapping function f (x). FIG. 5 represents the mapping function f (x) when the mapping control information α is “3”, “5”, and “50”.

As is understood from FIG. 5, the smaller the mapping control information α is, the larger the change amount of the f (x) in respect to the overall change of the sample value x in the mapping function f (x) which is used, and the amplitude conversion of the learning sound source signal is performed. When the mapping control information α is changed in this manner, the amplification amount in respect to the learning sound source signal changes.

Returning to the description of the flowchart of FIG. 9, in step S13, the speaker 355 reproduces the learning output signal which has been supplied from the mapping process unit 353.

Furthermore, more specifically, the learning output signal, which has been obtained by performing the mapping process on the predetermined section which includes the processing target sample, is reproduced. Here, the section which is the reproduction target, for example, is a section or the like formed from the sample which has been already specified by the mapping control information. In this case, mapping process is performed on each sample of the section which is the processing target using the mapping control information which has been designated for the samples, and the learning output signal, which has been obtained as a result thereof, is reproduced.

When the learning output signal is reproduced in this manner, the user evaluates the effect of the mapping process while listening to the audio which is output from the speaker 355. In other words, it is evaluated as to whether or not the volume of the audio of the learning output signal is appropriate. Furthermore, the user operated the input unit 351, and from the result of the evaluation, adjustment of the mapping control information is instructed, or finalization of the specified mapping control information, where the specified mapping control information is set as optimal mapping control information, is instructed.

In step S14, the mapping control information application unit 352 determines whether or not optimal mapping control information is obtained based on the signal according to the operation of the user which is supplied from the input unit 351. For example, when the finalization of the mapping control information is instructed by the user, it is determined that optimal mapping control information is obtained.

In step S14, when it is determined that optimal mapping control information still has not been obtained, in other words when adjustment of the mapping control information is instructed, the process returns to step S11, and the processes described above are repeated.

In this case, new mapping control information is applied to the sample of the processing target, and evaluation of the mapping control information is performed. In this manner, by evaluating the effect of the mapping process while actually listening to the audio of the learning output signal, optimal mapping control information may be applied from a standpoint of audibility.

Conversely, in step S14, when it is determined that optimal mapping control information is obtained, the process proceeds to step S15. In step S15, the mapping control information application unit 352 supplies the mapping control information, which has been applied to the processing target sample, to the mapping control model learning unit 357.

In step S16, the input analysis unit 356 analyses the characteristics of the supplied learning sound source signal, and supplies the analyzed feature value, which has been obtained as a result thereof, to the mapping control model learning unit 357.

For example, if the n-th sample of the learning sound source signal is assumed to be the processing target sample, the input analysis unit 356 performs calculation of the previously described Expression 1 and calculates the root mean square RMS (n) in respect to the n-th sample of the learning sound source signal as the analyzed feature value of the n-th sample.

Furthermore, in the present example, in expression 1, x (m) shows the sample value of m-th sample of the learning sound source signal (the value of the learning sound source signal). In addition, in Expression 1, the value or the learning sound source signal, in other words the sample value of each sample of the learning sound source signal is normalized so as to be −1≦x (m)≦1.

Therefore, the root mean square RMS (n) is obtained by taking the logarithm of the square root of the mean square of the sample value of the sample, which is included in the section formed from N sequential samples centered on the n-th sample, and multiplying the obtained value by the constant “20”.

The value of the root mean square RMS (n) which has been obtained in this manner decreases the smaller the absolute value of the sample value of each sample of the specified section centered on the n-th sample of the learning sound source signal which is the processing target is. In other words, the lower the volume of the audio of the entirety of the specified section which includes the processing target sample of the learning sound source signal, the smaller the root mean square RMS (n) is.

Furthermore, the root mean square RMS (n) is described as an example of the analyzed feature value, however, the analyzed feature value may be the t-th power value (where t≧2), the zero crossing rate of the learning sound source signal, the slope of the frequency envelope of the learning sound source signal, or the like, with regard to the RMS (n), or a combination of these, for example, the result of a weighted sum may also be used.

When the analyzed feature value is supplied to the mapping control model learning unit 357 from the input analysis unit 356 as described above, the mapping control model learning unit 357 associates, in regard to the processing target sample, the obtained analyzed feature value with the mapping control information of the sample and temporary records this.

In step S17, the learning apparatus 51 determines whether or not a sufficient number of items of mapping control information have been obtained. For example, when a sufficient number of sets of analyzed feature values and items of mapping control information, which are temporarily recorded, have been obtained to learn the mapping control model, is determined that a sufficient number of items of mapping control information have been obtained.

In step S17, when it is determined that a sufficient number of items of mapping control information have not been obtained, the process returns to step S11, and the processes described above are repeated. In other words, the next sample from the sample, which is the processing target at the present point of the learning sound source signal, is set as a new processing target sample, and the mapping control information is applied thereto, or the mapping control information is applied to the new sample of the learning sound source signal. In addition, the mapping control information may also be applied to the sample of the learning sound source signal according to different users.

In step S17, when it is determined that a sufficient number of items of mapping control information have been obtained, in step S18, the mapping control model learning unit 357 learns the mapping control model by using the set of the analyzed feature value and the mapping control information which is temporarily recorded.

For example, the mapping control model learning unit 357, by performing the calculation of Expression 6 shown below, assuming that mapping control information α may be obtained from the analyzed feature value, setting the function shown in Expression 6 to the mapping control model, obtains these by learning.

y=ax²+bx+c [Expression 6]

Furthermore, in Expression 6, x shows the analyzed feature value, and a, b, and c are constants. In particular, the constant c is an offset item with no correlation to the analyzed feature value x.

In this case, the mapping control model learning unit 66 sets the root mean square RMS (n) and the square value of the root mean square RMS (n), which correspond to x and x² in Expression 6, to the explanatory variable, sets the mapping control information α as the explained variable, performs learning of the linear regression model using the least squares method, and obtains model parameters a, b, and c.

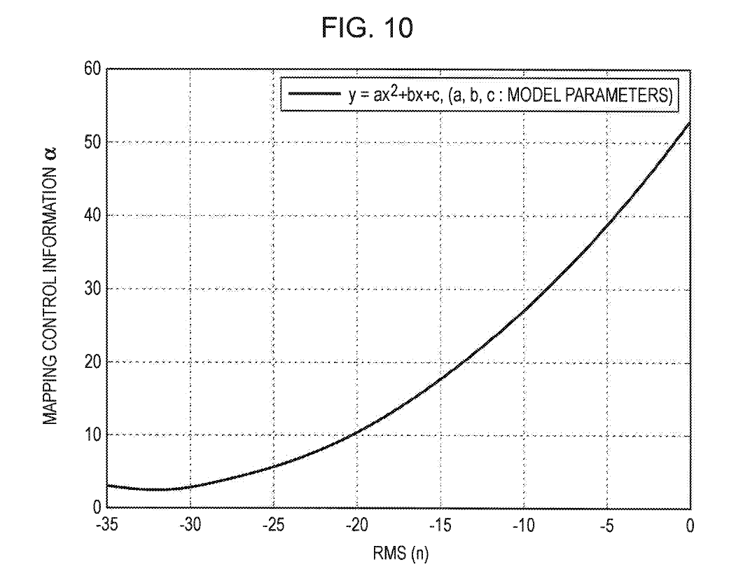

Therefore, for example, the result shown in FIG. 10 is obtained. Furthermore, in FIG. 10, the vertical axis shows the mapping control information α, and the horizontal axis shows the root mean square RMS (n) as an analyzed feature value. In FIG. 10, the curved line shows the value of the mapping control information α which is determined in regard to the value of each analyzed feature value, in other words the function graph shown in the above described Expression 6.

In this example, when the volume of the audio of the audio signal of the learning sound source signal, the input signal, or the like is small, the smaller the analyzed feature value is, the smaller the value of the mapping control information α also is.

When the constants a, b, and c in the function ax²+bx+c for obtaining the mapping control information from the analyzed feature value are determined according to learning such as described above, the mapping control model learning unit 357 supplies these constants to the recording unit 358 as model parameters of the mapping control model, and makes the recording unit 358 record them.

When the mapping control model which is obtained by learning is recorded in the recording unit 358, the learning process ends. The mapping control model which is recorded to the recording unit 358 is subsequently recorded to the recording unit of the audio signal processing apparatus 300 shown in FIG. 7 as a mapping control model 304 and used in the mapping process.

As described above, the learning apparatus 350 shown in FIG. 8 obtains the mapping control model by learning, by using a plurality of learning sound source signals, or mapping control information which is specified by a plurality of users for each of the audio signal processing apparatuses 300 shown in FIG. 7.

Therefore, if the obtained mapping control model is used, it becomes possible to obtain the statistically optimal mapping control information in regard to the audio signal processing apparatus 300 without depending on the user who listens to the input signal of the reproduction target or the reproduced sound. In particular, if learning is performed using only the mapping control information which is applied by one user, a mapping control model, which can obtain optimal mapping control information in regard to the user, may be generated.

Furthermore, in the above, a case in which the input or the adjustment of the mapping control information is performed per sample in regard to the learning sound source signal has been described as an example, however, the input or the adjustment of the mapping control information may also be performed per every two or more sequential samples of the learning sound source signal.

In addition, here, a quadratic expression related to the RMS (n) as a mapping control model is used, however, polynomial function of a degree of 3 or more may also be used.

In addition, description has been given that the root mean square RMS (n) and the square value thereof are used as the explanatory variables of the mapping control model, however, other analyzed feature values may also be arbitrarily added and combined as the explanatory variable. For example, as another analyzed feature value, the t-th power value (where t≧3), the zero crossing rate of the learning sound source signal, the slope of the frequency envelope of the learning sound source signal, or the like, with regard to the root mean square RMS (n), may be considered.

In this manner, the mapping control information determination unit 303 shown in FIG. 7 calculates the optimal mapping control information α which corresponds to the analyzed feature value which is input from the input analysis unit 302 by using the mapping control model 304 which is obtained using the learning process described with reference to FIG. 8 and FIG. 9, for example, the data of the correlation between the root mean square RMS (n) as the analyzed feature value shown in FIG. 10, and the mapping control information α, and outputs the optimal mapping control information α to the mapping control information adjustment unit 321.

Next, the mapping control information adjustment unit 321 performs adjustment of the mapping control information corresponding to the magnitude of the environmental sound in regard to the mapping control information α which is obtained from the mapping control information determination unit 303. This process is the same as the process of the first embodiment.

Below, the mapping process in the mapping process unit 322 is performed in the same manner as in the previously described first embodiment, the band restriction is performed in the band restriction unit 323, and the output signal is output via the speaker 324.

As described above, by performing adjustment of the mapping control information based on the analysis results of the environmental sound in addition to using the mapping control model based on the previously performed statistical analysis, the audio signal processing apparatus 300 of the third embodiment can obtain the optimal mapping control information corresponding to the magnitude of the environmental sound, and the optimal reproduction level control may be realized corresponding to the environment sound for the user.

### 4. Regarding the Fourth Embodiment

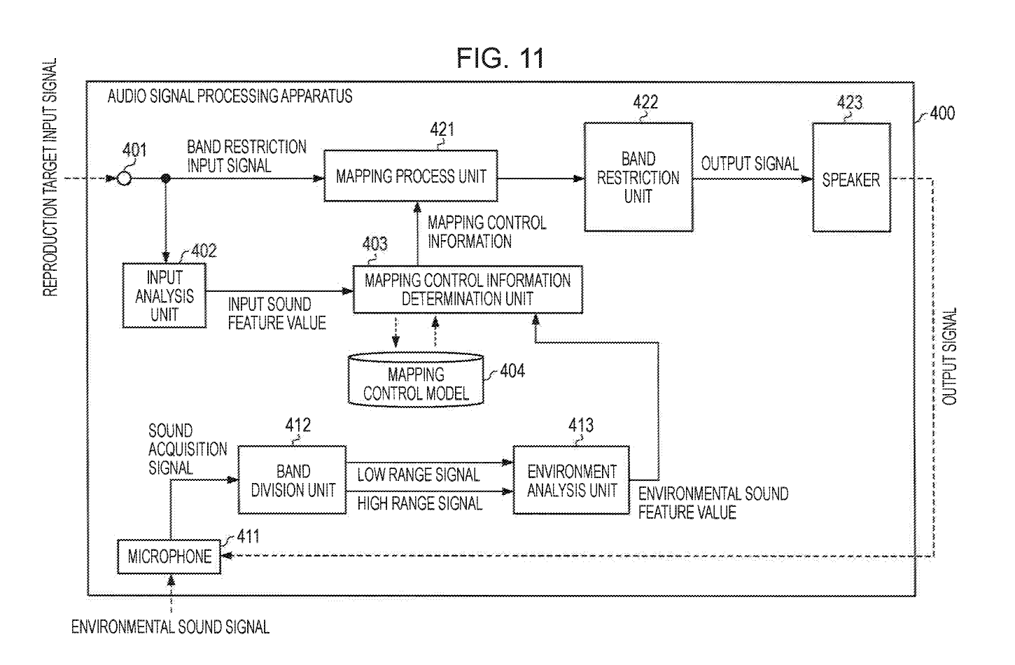

A block diagram of an audio signal processing apparatus 400 in the fourth embodiment of the present disclosure will be shown in FIG. 11.

The audio signal processing apparatus 400 shown in FIG. 11 is configured as shown below.

The audio signal processing apparatus 400 is configured by an input unit 401, an input analysis unit 402, a mapping control information determination unit 403, a mapping control model 404 (storage unit), a microphone 411, a band division unit 412, an environment analysis unit 413, a mapping process unit 421, a band restriction unit 422, and a speaker 423.

The difference between this and the configuration described with reference to FIG. 7 is that the mapping control information adjustment unit 321 shown in FIG. 7 is omitted.

Furthermore, the mapping control model 404 (storage unit) is different from the data shown in FIG. 7, and the fact that the data is generated with consideration of the environmental sound is different.

In the present embodiment, the mapping control information determination unit 403 is configured so as to generate the mapping control information which is applied in the mapping process unit 221.

In the audio signal processing apparatus 400 shown in FIG. 11, the input signal which is input from the input unit 401 is supplied to the input analysis unit 402 and the characteristics thereof are analyzed.

Next, in the same manner as the first embodiment of the present disclosure, band division is performed on the sound acquisition signal which is input via the microphone 411 in the band division unit 412, and is analyzed in the environment analysis unit 413.

The input sound feature value from the input analysis unit 402 and the environmental sound feature value from the environment analysis unit 413 are supplied to the mapping control information determination unit 403. This process is the same as the processes described in the first to third embodiments.

Next, in the mapping control information determination unit 403, the mapping control information from the analyzed feature value is obtained by using the mapping control model 404, which has been generated by the learning process which takes the environmental sound into consideration, and is supplied to the mapping process unit 421.

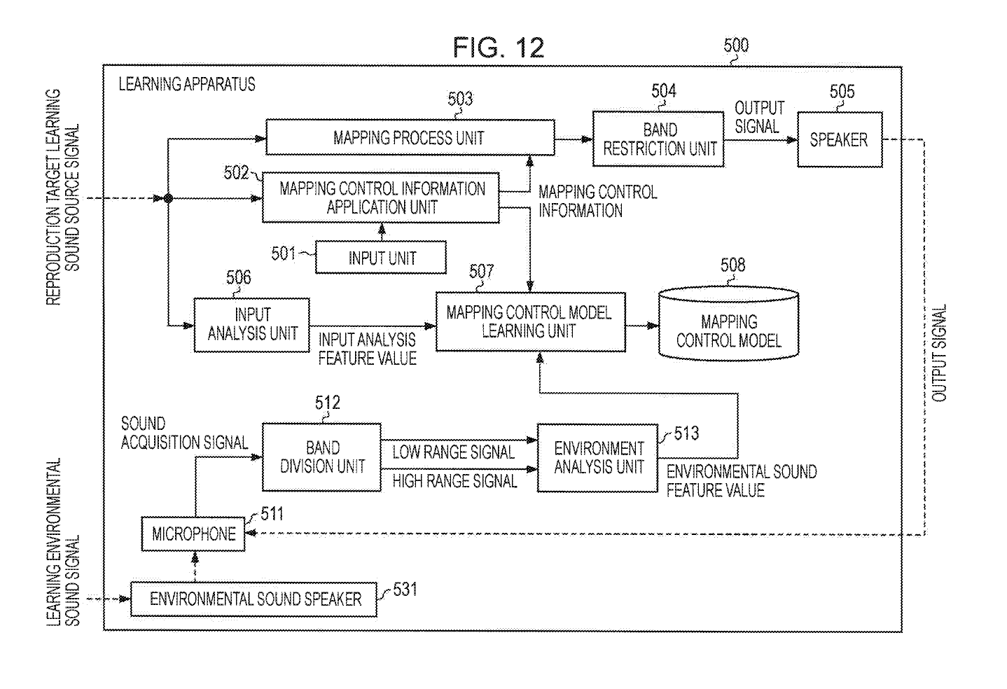

The mapping control model 404 is generated in, for example, the learning apparatus 500 shown in FIG. 12. The learning apparatus 500 shown in FIG. 12 is configured from an input unit 501, a mapping control information application unit 502, a mapping process unit 503, a band restriction unit 504, a speaker 505, an input analysis unit 506, a mapping control model learning unit 507, a recording unit 508, a microphone 511, a band division unit 512, an environment analysis unit 513, and an environmental sound speaker 531. Furthermore, the environmental sound speaker 531 may also be a speaker of an external apparatus. In the learning apparatus 500, the learning sound source signal used for the learning of the mapping control model is supplied to the mapping control information application unit 502, the input analysis unit 506, and the mapping process unit 503. In addition, the learning environmental sound signal is input to the microphone 511 via the environmental sound speaker 531.

The input unit 501 is, for example, formed from a button or the like which is operated by a user, and supplies a signal which corresponds to the operation of the user to the mapping control information application unit 502. The mapping control information application unit 502 applies the mapping control information to each sample of the supplied learning sound source signal according to the signal from the input unit 501, and supplies them to the mapping process unit 503 or the mapping control model learning unit 507.

The mapping process unit 503 performs mapping process on the supplied learning sound source signal by using the mapping control information from the mapping control information application unit 502, and supplies the learning output signal obtained as a result to the band restriction unit 504. The band restriction unit 504, for example, performs the band restriction process of the low range cut of the like, and supplies the process signal to the speaker 505. The speaker 505 reproduces audio based on the learning output signal which has been generated by the mapping process unit 503.

The input analysis unit 506 analyses the characteristics of the supplied learning sound source signal, and supplies the analyzed feature value which shows the analysis results thereof to the mapping control model learning unit 507. In addition, the sound acquisition signal, which includes the output signal of the environmental sound and the speaker 505 which are input via the microphone 511, is separated into the low range signal which is configured by the environmental sound and the high range signal in the band division unit 512, and the environment analysis unit 513 generates the feature value of the environmental sound, for example the RMS (k). The processes of the microphone 511 to the environment analysis unit 513 are the same as the processes executed by the other microphone to the environment analysis unit of the first embodiment.

The mapping control model learning unit 357 obtains the mapping control model using the statistical analysis, which uses the analyzed feature value which corresponds to the reproduction target learning sound signal from the input analysis unit 356, the environmental sound feature value which corresponds to the learning environmental sound from the environment analysis unit 513, and the mapping control information from the mapping control information application unit 502, and supplies the mapping control model to the recording unit 508.

The recording unit 508 records the mapping control model supplied from the mapping control model learning unit 507. In this manner, the mapping control model recorded to the recording unit 508 is recorded to the recording unit of the audio signal processing apparatus 400 shown in FIG. 12 as a mapping control model 404.

Furthermore, the learning apparatus 500 shown in FIG. 12 may be configured inside of the audio signal processing apparatus 400 shown in FIG. 11, and may also be configured as an external apparatus. When the learning apparatus 500 shown in FIG. 12 is configured inside of the audio signal processing apparatus 400 shown in FIG. 11, the constituent components of the audio signal processing apparatus 400 may be applied as the constituent components of the learning apparatus in regard to the constituent components which are common with the constituent components of the audio signal processing apparatus 400 shown in FIG. 11 among the constituent components of the learning apparatus shown in FIG. 12.

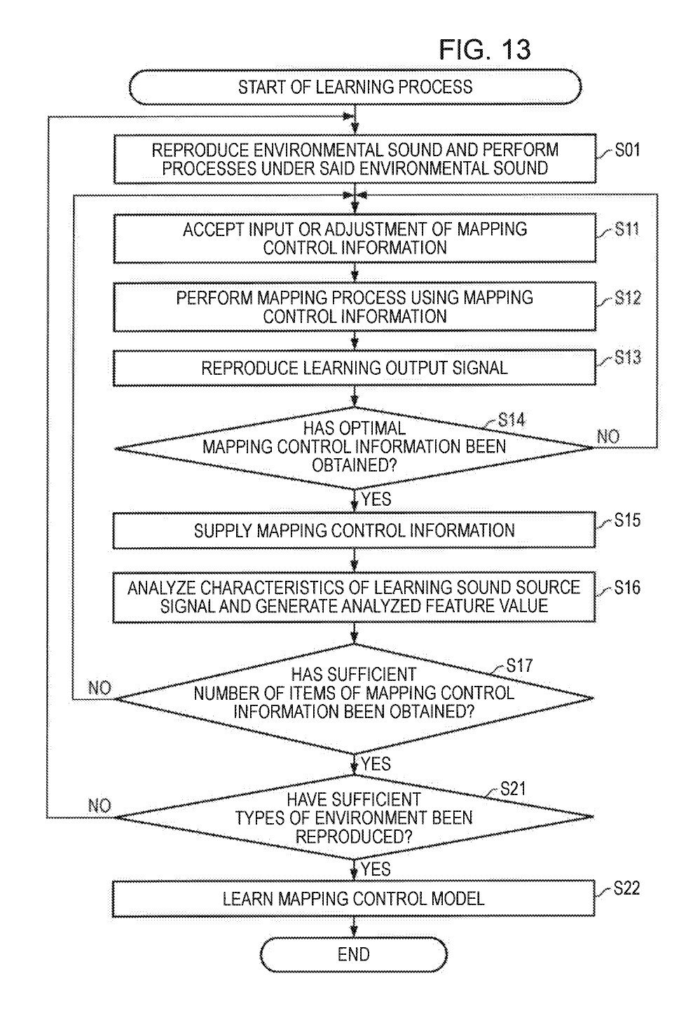

Next, the learning process of the learning apparatus 500 shown in FIG. 12 will be described with reference to the flowchart shown in FIG. 13.

As shown in step S01 of the flowchart shown in FIG. 13, firstly when the learning process is started, for example the environmental sound is reproduced in an audio-visual room from the environmental sound speaker 531 shown in FIG. 12, and the input or adjustment of the mapping control information is accepted in that environment.

The processes of step S11 to step S17 are the same as the processes of step S11 to step S17 shown in FIG. 9 described earlier with reference to the flowchart of FIG. 9.

The input sound feature value is obtained using these processes according to the analysis processing of the characteristics of the learning sound source signal under a single environmental sound which is reproduced in step S01.

In addition, band division is performed on the sound acquisition signal in an environment in which reproduction is taking place, the characteristics of the divided signal are analyzed, and the environmental sound feature value is obtained. This is repeated in the same environment until a sufficient number of items of mapping control information are obtained.

Furthermore, in step S21, after a sufficient number of items of mapping control information have been obtained, the next environmental sound is reproduced and a sufficient number of items of mapping control information are gathered in the same manner in that environment.

This is performed for a sufficient number of environmental sounds. For example, m types of different learning environmental sounds SRS1 to SRSm are prepared in advance, and a sufficient number of items of mapping control information are gathered in an environment of these m types of different learning environmental sounds SRS1 to SRSm. After a sufficient number of environmental sounds have been reproduced, the mapping control model is learned in step S22.

Furthermore, in the learning apparatus 350 in the third embodiment which has been described with reference to FIG. 8 earlier, only the input sound feature value of the learning sound source, which corresponds to the reproduction target sound which is input from the input analysis unit 356, set as the explanatory variable, however, the learning apparatus 500 shown in FIG. 12 obtains the mapping control model where both of the input sound feature value of the learning sound source which corresponds to the reproduction target sound, and the environmental sound feature value from the environment analysis unit 513 which is analyzed corresponding to the learning environmental sound are used as explanatory variables.

The mapping control model which is calculated in the present embodiment is the data of the correlation between the root mean square RMS (n) as the analyzed feature value of the reproduction target signal described earlier with reference to FIG. 10, and the mapping control information α, and is configured by a plurality of items of data in which the data of the correlation is further set for each environmental sound (the previously described learning environmental sound SRS1 to SRSm). Alternatively, the data of the correlation may also be set as three-dimensional data in which the root mean square RMS (n) as the analyzed feature value of the reproduction target signal, the root mean square RMS (k) as the analyzed feature value of the environmental sound, and the mapping control information α are set as the x y z axes. In the present embodiment, a mapping control model, in which it is possible to obtain an optimal mapping control information α from the analyzed feature value of the reproduction target signal and the analyzed feature value of the environmental sound, is generated.

Furthermore, in the learning apparatus shown in FIG. 12, an example is described in which the speaker which outputs the environmental sound is set as a monaural speaker, however, the environmental sound may also be reproduced using a speaker of two channels or more. Alternatively, the input or the adjustment of the mapping control information may be performed in an actual environment.

In this manner, the mapping control information determination unit 403 shown in FIG. 11 calculates the optimal mapping control information α which corresponds to the analyzed feature value which is input from the input analysis unit 402 by using the mapping control model 404 obtained using the learning process described with reference to FIG. 12 and FIG. 13, and the environmental sound feature value which is input from the environment analysis unit 513 outputs the optimal mapping control information α to the mapping process unit 421.

Next, the mapping process unit 421 performs a mapping process which is the same as that of second embodiment described earlier, and outputs the result of the mapping process to the band restriction unit 422. The band restriction unit 422 performs band restriction which is the same as that of the first embodiment described earlier, and outputs the output signal via the speaker 423.

As described above, the audio signal processing apparatus 400 of the present embodiment shown in FIG. 11 is of a configuration which applies the mapping control model which is based on the statistical analysis to which the learning process performed in advance, in other words the learning data, is applied. The mapping control model in the present embodiment uses both of the analysis results of the input signal which is a reproduction target signal, and the analysis results of the environmental sound as explanatory variables, and the optimal mapping control information corresponding to the magnitude of the environmental sound may be obtained, and the optimal reproduction level control may be realized corresponding to the environment for the user.

### 5. Regarding the Fifth Embodiment

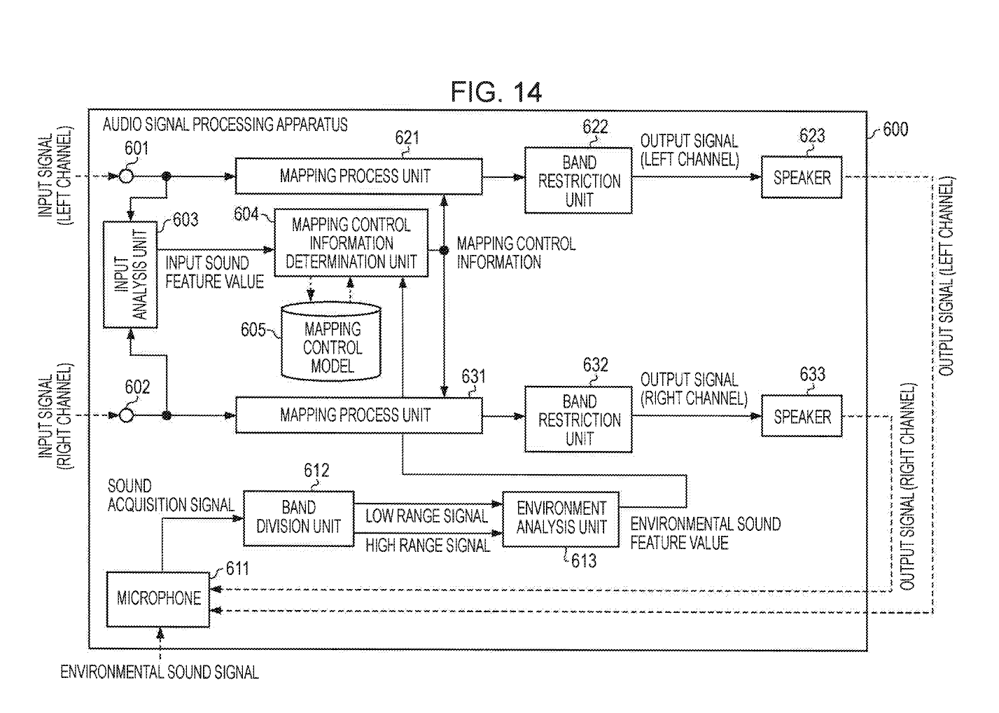

Next, the fifth embodiment of an audio signal processing apparatus of the present disclosure will be described with reference to the FIG. 14.

In the audio signal processing apparatus 600 shown in FIG. 14, the input signal which is the reproduction target is configured by a plurality of signals of the right channel and the left channel. In this manner, when the number of channels of the audio signal two or more, since the volume balance changes when performing the independent amplitude conversion per channel, it is preferable to perform the same amplitude conversion in all of the channels.

The audio signal processing apparatus 600 shown in FIG. 14 includes an input unit 601 of the left channel input signal, an input unit 602 of the right channel input signal, and an input analysis unit 603 which performs the analysis process of the left and right channel input signals. Furthermore, the audio signal processing apparatus 600 includes the mapping control information determination unit 604 which applies the mapping control model 605 based on the input sound feature value from the input analysis unit 603 and determines the mapping control information, and a storage unit which stores the mapping control model 605. Furthermore, the mapping control model is the same data as that of the mapping control model 404 shown in FIG. 11 which has been used in the previously described fourth embodiment.

Furthermore, the audio signal processing apparatus 600 shown in FIG. 14 is configured as shown below. The audio signal processing apparatus 600 is configured by the microphone 611 which acquires the environmental sound, the band division unit 612 which inputs the sound acquisition signal from the microphone 611 and performs band division, and the environment analysis unit 613 which acquires the feature value of the low range signal which is included in the environmental sound generated by the band division unit 612. These components are the same as those described in the first embodiment earlier.

Furthermore, the audio signal processing apparatus 600 shown in FIG. 14 is configured as shown below. The audio signal processing apparatus 600 is configured by the mapping process unit 621 which performs the mapping process of the left channel input signal, the band restriction unit 522 which performs the band restriction process on the result of the mapping process of the left channel input signal, the speaker 623 which outputs the result of the band restriction of the left channel input signal, the mapping process unit 631 which performs the mapping process on the right channel input signal, the band restriction unit 632 which performs the band restriction process on the result of the mapping process of the right channel input signal, and the speaker 633 which outputs the result of the band restriction of the right channel input signal.

The characteristics of the reproduction target input signal of the left and channels which are input from the input units 601 and 602 are analyzed in the input analysis unit 603, and the input sound feature value which is common to the left and right channels is obtained. In addition, band division is performed in the band division unit 612 in regard to the signal which is input from the microphone 611, the characteristics thereof are analyzed in the environment analysis unit 613, and the environmental sound feature value is obtained.

The input sound feature value generated by the input analysis unit 603 and the environmental sound feature value generated by the environment analysis unit 613 are supplied to the mapping control information determination unit 604.

The mapping control information determination unit 604 applies the mapping control model 605 which is the same as in the fourth embodiment described with reference to FIG. 11 earlier, and obtains the mapping control information. The mapping control information is the same in the left and right channels.

The mapping control information is output to the two mapping process units of the mapping process unit 621 which performs the mapping process of the left channel input signal and the mapping process unit 631 which performs the mapping process of the right channel input signal, and the mapping process is performed per channel.

Subsequently, band restriction is performed in the band restriction units 622 and 632 on the signals of each channel to which the mapping process is performed, and the output signal is output via the speakers 623 and 633.

Furthermore, the configuration shown in FIG. 14 is an example in which the input signal is of two channels, however, when there are three or more input signals, it is favorable to provide an input unit, a mapping process unit, a band restriction unit, and a speaker for each channel.

As described above, when there is a plurality of input signals, a common item of mapping control information is generated, the common item of mapping control information is applied, and the same amplitude conversion is performed in all of the channels. In such a process, it is possible to realize an audio signal processing method and apparatus in which it is possible to emphasize the reproduction level of the audio signal without changing the volume balance between channels.

### 6. Regarding the Sixth Embodiment

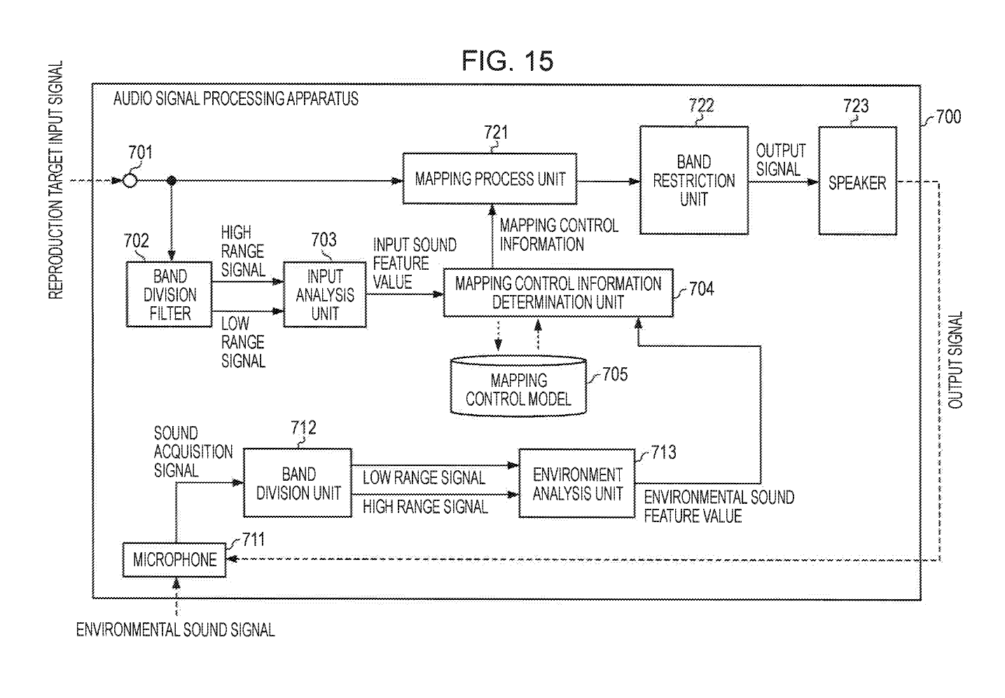

Next, the configuration and processes of the audio signal processing apparatus 700 according to the sixth embodiment of the present disclosure will be described with reference to the FIG. 15.

The audio signal processing apparatus 700 shown in FIG. 15 has a configuration where the reproduction target input signal, which is input via the input unit 701, is input to the band division filter 702, the input signal is separated into a high range signal and a low range signal, and processing is performed. The other configurations are the same as in the fourth embodiment described earlier with reference to FIG. 11.

The characteristics of audio and music differ according to the frequency band. Therefore, by performing the appropriate analysis per frequency hand, it is possible to obtain an analyzed feature value which is more suitable for processing and audibility.

In the audio signal processing apparatus 700 shown in FIG. 15, the reproduction target input signal which is input from the input unit 701 is divided into a low range signal and a high range signal which are band restricted at approximately 300 Hz by the hand division filter 702 and are supplied to the input analysis unit 703. Furthermore, in the input analysis unit 703, different analysis is performed respectively on the low range signal and the high range signal, and the common analyzed feature value is obtained from the results thereof.

The input analysis unit 703 performs different analysis respectively on the low range signal and the high range signal, and obtains the common analyzed feature value from the results thereof according to, for example, the Expression 7 to Expression 9 shown below.

Expression 7 is a formula for computation of the root mean square RMS_{—}1 (n) as the feature value which corresponds to the n-th sample of the low range signal.

Expression 8 is a formula for computation of the root mean square RMS_h (n) as the feature value which corresponds to the n-th sample of the high range signal.

The root mean square RMS_{—}1 (n) and RMS_h (n) of the N and M samples centered on the n-th sample of each of the band division signals are respectively calculated.

$$\begin{matrix}RMS\_l ( n ) = 20.0 \times {log}_{10} ( \sqrt{\frac{1}{M} \cdot {\sum }_{m = n - M / 2}^{m + M / 2 - 1} {x\_l}^{2} ( m )} ) & [ Expression 7 ] \\ RMS\_h ( n ) = 20.0 \times {log}_{10} ( \sqrt{\frac{1}{N} \cdot {\sum }_{m = n - N / 2}^{m + N / 2 - 1} {x\_h}^{2} ( m )} ) & [ Expression 8 ]\end{matrix}$$

In the above described Expression 7 and Expression 8, x_{—}1 and x_h are a to range signal and a high range signal which were obtained from the reproduction target input signal x using the band division filter, and for example, they are signals in which the power levels have been normalized to from −1.0 to 1.0.

The input analysis unit 703 performs a weighted sum calculation on each of the values of the feature value RMS_{—}1 (n) of the low range signal which is output according to Expression 7 above, and the feature value RMS_h (n) of the high range signal which is output according to Expression 8 above, using the weights a and b which are defined in advance according to Expression 9 shown below, and obtains the analyzed feature value RMS′ (a) common to the low range signal and the high range signal. Furthermore, the weights a and b are, for example, set to =a=b=0.5.

RMS′(n)=a×RMS_{—l}(n)+b×RMS_{—h}(n) (a=b=0.5) [Expression 9]

The RMS′ (n) obtained according to the Expression 9 above is set to the analyzed feature value of the reproduction target input signal.

Here, the obtained. RMS′ (n) is supplied to the mapping control information determination unit 704 as the input sound feature value in regard to the n-th reproduction target input signal.

Furthermore, in the Expression 9 above, the weights a and b are equal, however, they may also be set to apply a large weight on a signal of a specific band. In addition, in the above process example, the frequency band of the input signal is divided into two at 300 Hz, however, if it is within the band restriction of the band restriction unit 722, the analyzed feature value may be obtained from a signal which is divided at another frequency such as 200 Hz, 400 Hz, 1 kHz, or 3.4 kHz, or a signal which is divided into band signals of three or more divisions. Further in addition, different analysis is performed respectively on the input signals and the band division signals, and a combination of the results thereof may be set to the analyzed feature value. It is favorable to use an analysis which is suitable for the processing effect and the mapping function as the analyzed feature value. In addition, here, the filter is used for hand division, however, the signal of each band on the frequency axis may also be generated.

The input analysis unit 703 supplies the analyzed feature value obtained in this manner to the mapping control information determination unit 704.

Below, the mapping control information is obtained by applying the mapping control model 705 which is the same as in the fourth embodiment described with reference to FIG. 11 earlier. The mapping control information is output to the mapping process unit 721 and the mapping process is executed. Subsequently, band restriction is performed in the band restriction unit 722 on the signal to which the mapping process has been performed, and the output signal is output via the speaker 723.

In the present embodiment, a configuration is adopted in which the feature values corresponding to each band of the input signal are separately acquired, and the result of the weighted sum of each feature value is calculated as the feature value in regard to the input signal. Therefore, by performing the appropriate analysis per frequency band, it is possible to obtain an analyzed feature value which is more suitable for processing and audibility.

### 7. Regarding the Seventh Embodiment

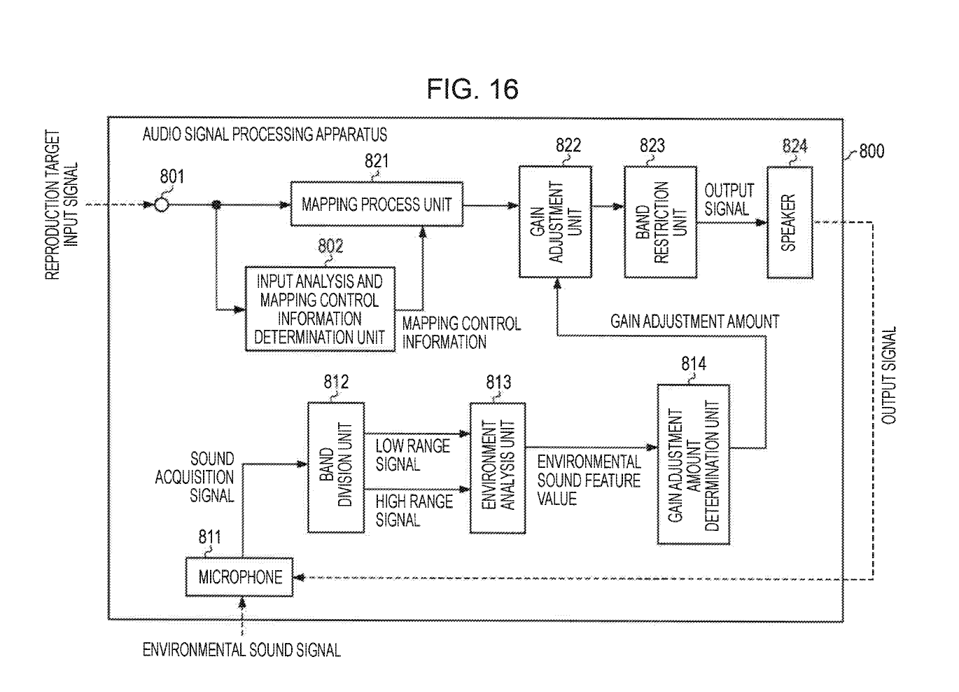

Next, the configuration and processes of the audio signal processing apparatus 800 according to the seventh embodiment of the present disclosure will be described with reference to the FIG. 16. The audio signal processing apparatus 800 shown in FIG. 16 has a configuration in which, after the mapping process is performed according to the characteristics of the input signal, the gain adjustment is performed linearly to correspond to the magnitude of the environmental sound.

A block diagram of an audio signal processing apparatus 800 according to the seventh embodiment of the present disclosure is shown in FIG. 16.

The audio signal processing apparatus 800 shown in FIG. 16 is configured as shown below.

The audio signal processing apparatus 800 is configured by an input unit 801, an input signal analysis and mapping control information determination unit 802, a microphone 811, a band division unit 812, an environment analysis unit 813, a gain adjustment amount determination unit 814, a mapping process unit 821, a gain adjustment unit 822, a band restriction unit 823, and a speaker 824.

The difference between this and the second embodiment described with reference to FIG. 6 is that the gain adjustment amount determination unit 814 and the gain adjustment unit 822 were added. The other configurations and the processes are the same as in the second embodiment.

In the reproduction target input signal which is input via the input unit 801, the mapping control information is calculated in the input signal analysis and mapping control information determination unit 802.

The mapping process unit 821 performs the mapping process based on the mapping control information and supplies it to the gain adjustment unit 822.

The processes of the microphone 811 to the band division unit 812 to the environment analysis unit 813 are the same as the previously described processes of the first embodiment. The analyzed feature value of the environmental sound is obtained in the environment analysis unit 813 and supplied to the gain adjustment amount determination unit 814.

The gain adjustment amount determination unit 814 determines the gain adjustment amount using the statistical model based on the table, the function, or the previously performed statistical analysis from the analyzed feature value of the environmental sound obtained from the environment analysis unit 813.

The gain adjustment amount determination unit 814, for example, obtains the gain adjustment amount by using the process shown below.

The root mean square RMS (k) of K samples centered on the k-th sample of the low range signal, which includes the environmental sound feature value which is the analyzed feature value of the environmental sound obtained from the environment analysis unit 813, in other words only the environmental sound, is set to x, and the gain adjustment amount y is obtained using the linear function of Expression 10 which is shown below.

y=ax+b [Expression 10]

Furthermore, here, the root mean square EMS (k) is used as the environmental sound feature value, however, another feature value or a combination thereof may also be used in the same manner as each of the previously described embodiments.

Furthermore, the linear function shown in Expression 10 is used for the calculation of the gain adjustment amount y, however, a non-linear function, a table, a linear regression model, or a non-linear regression model, which represents the relationship between the environmental sound feature value and the gain adjustment amount, may also be used.

The gain adjustment amount determination unit 814 calculates the gain adjustment amount y in this manner according to the feature value of the environmental sound and outputs it to the gain adjustment unit 822.

The gain adjustment unit 822 performs gain adjustment linearly in regard to the mapping process signal, which is input from the mapping process unit 821, based on the gain adjustment amount which is input from the gain adjustment amount determination unit 814.

Finally, the band restriction unit 823 applies the band restriction filter to the mapping process signal to which gain adjustment is performed, generates a band restricted output signal, and outputs it via the speaker 824.

In the configuration of the present embodiment, it is possible to obtain the output signal, to which gain adjustment is performed, according to the magnitude of the environmental sound.

### 8. Regarding the Eighth Embodiment

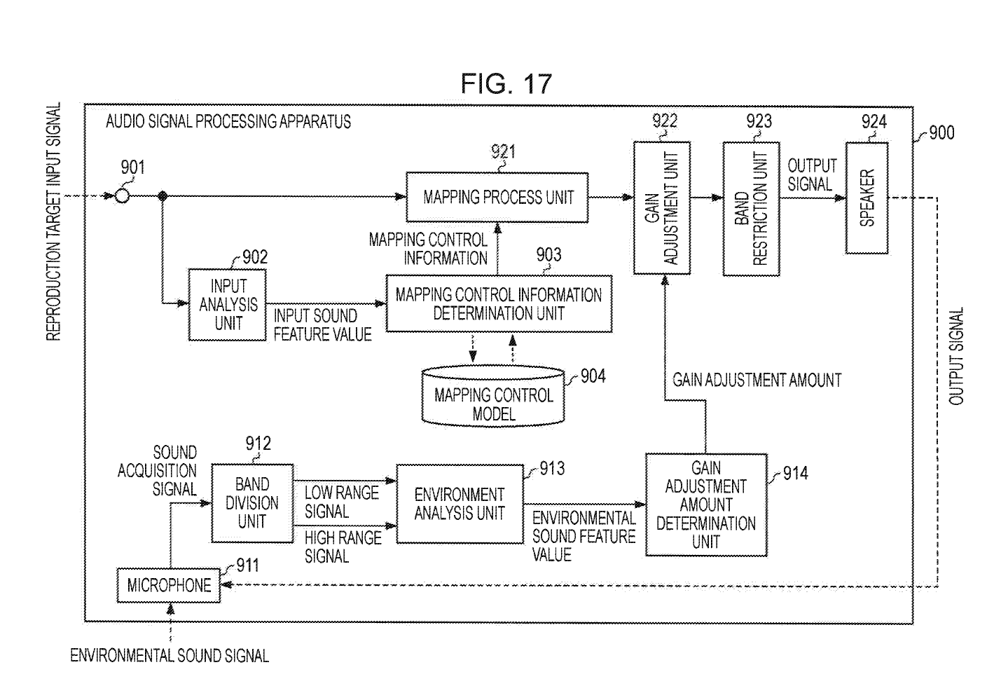

Next, the eighth embodiment of the present disclosure will be described with reference to FIG. 17.

The audio signal processing apparatus 900 shown in FIG. 17 has a configuration in which the same gain adjustment amount determination unit 914 and gain adjustment unit 922 as in the seventh embodiment described with reference to FIG. 16 are added to the audio signal processing apparatus 400 according to the fourth embodiment, which has been described with reference to FIG. 11 earlier.

The audio signal processing apparatus 900 shown in FIG. 17 is configured as shown below.

The audio signal processing apparatus 900 is configured by an input unit 901, an input analysis unit 902, a mapping control information determination unit 903, a mapping control model 904 (storage unit), a microphone 911, a band division unit 912, an environment analysis unit 913, a gain adjustment amount determination unit 914, a mapping process unit 921, a gain adjustment unit 922, a band restriction unit 923, and a speaker 924.

The characteristics of the reproduction target input signal which is input, from the input unit 901 are analyzed in the input, analysis unit 902, and the input sound feature value is obtained. In addition, band division is performed in the band division unit 912 in regard to the signal which is input from the microphone 911, the characteristics thereof are analyzed in the environment analysis unit 913, and the environmental sound feature value is obtained.

The input sound feature value generated by the input analysis unit 902 and the environmental sound feature value generated by the environment analysis unit 913 are supplied to the mapping control information determination unit 903.

The mapping control information determination unit 903 applies the mapping control model 904 which is the same as in the fourth embodiment described with reference to FIG. 11 earlier, and obtains the mapping control information.

The mapping control information is output to the mapping process unit 921 and the mapping process is executed.

The gain adjustment amount determination unit 914 calculates the gain adjustment amount y according to the feature value of the environmental sound and outputs the gain adjustment amount to the gain adjustment unit 922 in the same manner as in the seventh embodiment described with reference to FIG. 16 earlier. The gain adjustment unit 922 performs gain adjustment linearly in regard to the mapping process signal, which is input from the mapping process unit 921, based on the gain adjustment amount which is input from the gain adjustment amount determination unit 914.

Finally, the band restriction unit 923 applies the band restriction filter to the mapping process signal to which gain adjustment had been performed, generates a band restricted output signal, and outputs it via the speaker 924. In the configuration of the present embodiment, it is possible to obtain the output signal, to which gain adjustment is performed, according to the magnitude of the environmental sound.

### 9. Summary of the Configurations of the Present Disclosure

In the above, a detailed explanation is given of the embodiments of the present disclosure while giving reference to specific embodiments. However, it is clear that a person skilled in the art may achieve corrections and replacements of the embodiments within a scope that the spirit of the present disclosure is not departed from. In other words, the present technology is disclosed in the form of examples and should not be interpreted restrictively. In order to judge the spirit of the present disclosure, it is recommended to consult the claims section.

Furthermore, the technology disclosed in the present specification may be configured as described below.

(1) An audio signal processing apparatus which includes an input analysis unit which analyses the characteristics of an input signal and generates an input sound feature value; an environment analysis unit which analyses the characteristics of the environmental sound and generates an environmental sound feature value; a mapping control information generation unit which generates mapping control information as control information of amplitude conversion processing to the input signal by application of the input sound feature value and the environmental sound feature value; and a mapping process unit which performs amplitude conversion on the input signal based on a linear or non-linear mapping function determined according to the mapping control information and generates an output signal.

(2) The audio signal processing apparatus disclosed in (1), in which the mapping control information generation unit includes a mapping control information determination unit which generates preliminary mapping control information by application of the input sound feature value; and a mapping control information adjustment unit which generates the mapping control information which is output to the mapping process unit by an adjustment process in which the environmental sound feature value is applied to the preliminary mapping control information.

(3) The audio signal processing apparatus disclosed in (1) or (2), in which the input analysis unit calculates a root mean square calculated by using a plurality of sequential samples which are defined in advance as the input sound feature values; the environment analysis unit calculates a root mean square calculated by using a plurality of sequential samples of the environmental sound signal as the environmental sound feature value; and the mapping control information generation unit generates the mapping control information by using the root mean square of the input signal which is the input sound feature value and the root mean square of the environmental sound signal which is the environmental sound feature value.

(4) The audio signal processing apparatus disclosed in any one of (1) to (3), in which the input sound feature value and the environmental sound feature value are a mean square, a logarithm of a mean square, a root mean square, a logarithm of a root mean square, the zero crossing rate, the slope of a frequency envelope, or the result of a weighted sum of all of the above, with regard to a feature value calculation target signal.

(5) The audio signal processing apparatus disclosed in any one of (1) to (4), in which the environment analysis unit calculates the environmental sound feature values by executing feature analysis of a signal of a band of a high occupancy ratio of the environmental sound which is divided by a band division process from a sound acquisition signal acquired via a microphone.

(6) The audio signal processing apparatus disclosed in any one of (1) to (5), in which the audio signal processing apparatus has a band restriction unit which executes a band restriction process of a signal, to which a mapping process is applied, in the mapping process unit, and a signal is output via a speaker after band restriction in the band restriction unit.

(7) The audio signal processing apparatus disclosed in any one of (1) to (6), in which the mapping control information generation unit applies a mapping control model generated by a statistical analysis process to which a signal for learning, which includes an input signal and an environmental sound signal, is applied, and generates the mapping control information.

(8) The audio signal processing apparatus disclosed in (7), in which the mapping control model is data in which the mapping control information is associated with the various types of the input signal and the environmental sound signal.

(9) The audio signal processing apparatus disclosed in any one of (1) to (8), in which the input signal includes a plurality of input signals of a plurality of channels, and the mapping process unit is configured to execute separate mapping processes on each of the input signals.

(10) The audio signal processing apparatus disclosed in any one of (1) to (9), in which the audio processing apparatus further includes a gain adjustment unit which executes gain adjustment corresponding to the environmental sound feature value generated by the environment analysis unit in regard to a mapping process signal generated by the mapping process unit.

Furthermore, the program which executes the methods and processes of execution in the above described apparatus and the like is also included in the configuration of the present disclosure.

In addition, it is possible to perform execution of the series of processes which were described in the specification according to the hardware, the software, or the combined configuration of both of these. When executing the process using software, it is possible to either install a program, to which the process sequence is recorded, into the memory inside a computer, which is built into dedicated hardware, and execute the program, or, to install a program into a generic computer, which is able to execute each process, and execute the program. For example, the program may be recorded onto the recording medium in advance. Besides installing the program to a computes from a recording medium, the program may be received via a network such as a LAN (Local Area Network) or the Internet, and installed to a recording medium such as an internal hard disk.

Furthermore, each type of process described in the specification, besides being executed in time series according to the disclosure, may be executed in parallel or individually according to the processing ability of the apparatus which performs the processes, or as necessary. In addition, the system in the present specification is a logical collection of configurations of a plurality of apparatuses, and the apparatus of each configuration is not limited to being within the same housing.

The present disclosure contains subject matter related to that disclosed in Japanese Priority Patent Application JP 2011-226945 filed in the Japan Patent Office on Oct. 14, 2011 and Japanese Priority Patent Application JP 2012-020463 filed in the Japan Patent Office on Feb. 2, 2012, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An audio signal processing apparatus comprising:
an input analysis unit which analyses characteristics of an input signal and generates an input sound feature value;
an environment analysis unit which analyses characteristics of an environmental sound and generates an environmental sound feature value;
a mapping control information generation unit which generates mapping control information as control information of amplitude conversion processing to the input signal by application of the input sound feature value and the environmental sound feature value; and
a mapping process unit which performs amplitude conversion on the input signal based on a linear or non-linear mapping function determined according to the mapping control information and generates an output signal.

2. The audio signal processing apparatus according to claim 1,
wherein the mapping control information generation unit includes
a mapping control information determination unit which generates preliminary mapping control information by application of the input sound feature value; and
a mapping control information adjustment unit which generates the mapping control information which is output to the mapping process unit by an adjustment process in which the environmental sound feature value is applied to the preliminary mapping control information.

3. The audio signal processing apparatus according to claim 1,
wherein the input analysis unit calculates a root mean square calculated by using a plurality of sequential samples which are defined in advance as the input sound feature values;
the environment analysis unit calculates a root mean square calculated by using a plurality of sequential samples of an environmental sound signal as the environmental sound feature value; and
the mapping control information generation unit generates the mapping control information by using the root mean square of the input signal which is the input sound feature value and the root mean square of the environmental sound signal which is the environmental sound feature value.

4. The audio signal processing apparatus according to claim 1,
wherein the input sound feature value and the environmental sound feature value are a mean square, a logarithm of a mean square, a root mean square, a logarithm of a root mean square, a zero crossing rate, a slope of a frequency envelope, or a result of a weighted sum of all of these, with regard to a feature value calculation target signal.

5. The audio signal processing apparatus according to claim 1,
wherein the environment analysis unit calculates the environmental sound feature values by executing feature analysis of a signal of a band of a high occupancy ratio of the environmental sound which is divided by a band division process from a sound acquisition signal which is acquired via a microphone.

6. The audio signal processing apparatus according to claim 1 further comprising:
a band restriction unit which executes a band restriction process of a signal, to which a mapping process is applied, in the mapping process unit,
wherein a signal is output via a speaker after band restriction in the band restriction unit.

7. The audio signal processing apparatus according to claim 1,
wherein the mapping control information generation unit applies a mapping control model generated by a statistical analysis process to which a signal for learning, which includes an input signal and an environmental sound signal, is applied, and generates the mapping control information.

8. The audio signal processing apparatus according to claim 7,
wherein the mapping control model is data in which the mapping control information is associated with various types of the input signal and the environmental sound signal.

9. The audio signal processing apparatus according to claim 1,
wherein the input signal includes a plurality of input signals of a plurality of channels, and the mapping process unit is configured to execute separate mapping processes on each of the input signals.

10. The audio signal processing apparatus according to claim 1 further comprising:
a gain adjustment unit which executes gain adjustment corresponding to the environmental sound feature value generated by the environment analysis unit in regard to a mapping process signal generated by the mapping process unit.

11. An audio signal processing method which is executed in an audio signal processing apparatus comprising:
analyzing characteristics of an input signal and generating an input sound feature value;
analyzing characteristics of an environmental sound and generating an environmental sound feature value;
generating mapping control information as control information of amplitude conversion processing to the input signal by application of the input sound feature value and the environmental sound feature value; and
performing amplitude conversion on the input signal based on a linear or non-linear mapping function determined according to the mapping control information and generates an output signal.

12. A program which executes audio signal processing in an audio signal processing apparatus comprising:
analyzing characteristics of an input signal and generating an input sound feature value;
analyzing characteristics of an environmental sound and generating an environmental sound feature value;
generating mapping control information as control information of amplitude conversion processing to the input signal by application of the input sound feature value and the environmental sound feature value; and
performing amplitude conversion on the input signal based on a linear or non-linear mapping function determined according to the mapping control information and generates an output signal.
